(19) United States
(12) Patent Application Publication
(10) Pub. No.: US 2024/0354481 A1
(43) Pub. Date: Oct. 24, 2024

(54) SYSTEMS AND METHODS FOR MIXED-SIZE PLACEMENT

(71) Applicant: The Research Foundation for The State University of new York, Binghamton, NY (US)

(72) Inventor: Patrick Madden, Vestal, NY (US)

(21) Appl. No.: 18/634,860

(22) Filed: Apr. 12, 2024

Related U.S. Application Data
(60) Provisional application No. 63/459,239, filed on Apr. 13, 2023.

(51) Int. Cl. G06F 30/392

(52) U.S. Cl. CPC G06F 30/392

(57) ABSTRACT

A system and method of laying out an integrated circuit, comprising defining a netlist of circuit elements comprising a plurality of macro blocks and standard cells of the integrated circuit, each macro block and standard cell having a respective area requirement; obtaining and storing a hierarchical abstract relative positioning (SHARP) of the circuit elements by at least one of repeatedly partitioning the netlist using bisection, and inducing cut lines into an abstract placement generated by an analytic placement tool; defining a plurality of arrangements of the macro blocks and standard cells within a respective region utilizing the SHARP; legalizing the plurality of arrangements to form legalized regions, each legalized region meeting the area requirements of the circuit elements within each respective region; and merging the legalized regions to generate a set of potential placements.

### CROSS REFERENCE TO RELATED APPLICATIONS

The present application is a non-provisional of, and claims benefit of priority under 36 U.S.C. § 119 (e) from, U.S. Provisional Patent Application No. 63/459,239, filed Apr. 13, 2023, the entirety of which is expressly incorporated herein by reference.

### FIELD OF THE INVENTION

The present invention relates to the field of floor planning, and in particular systems and method for automatic floor planning of complex integrated circuits.

### BACKGROUND OF THE INVENTION

For years, integrated circuit design has been a driver for algorithmic advances. The problems encountered in the design of modern circuits are often intractable, and with exponentially increasing size. Efficient heuristics and approximations have been essential to sustaining Moore's Law growth, and now almost every aspect of the design process is heavily automated.

There is, however, one notable exception: there is often substantial floor planning effort from human designers to position large macro blocks. The lack of full automation on this step has motivated the exploration of novel optimization methods, most recently with reinforcement learning.

### INTRODUCTION

From the start of the computing revolution, optimization and algorithmic efficiency have been key concerns. Many of the techniques that are in wide use today have their roots in design automation problems—simulated annealing {33} and hill-climbing based partitioning methods {34, 35} among them. Circuit design also leverages mathematical techniques developed elsewhere; from algebra to calculus to dynamic programming, almost every optimization tool has found an application within design automation.

In recent years, there has been a significant advance in machine learning, which is now being applied in to a wide range of problems. Within design automation, recent results for mixed size placement {36} have attracted a great deal of attention. The growth of machine learning in design automation is the impetus for a panel discussion at ISPD 2022, and this paper is meant to serve as a companion to this discussion, highlighting key ideas and providing a reference to related works.

### Circuit Placement

Many of the fundamental problems encountered in designing a circuit are intractable, with no known polynomial time algorithms {37}. Even when “optimal” algorithms exist, they can too slow for problems that grow in lock step with Moore's Law.

An exceptionally challenging part of the placement design flow comes in with the floor planning of large macro blocks—this is a two-dimensional bin packing problem.

If a designer needs to floor plan a set of macro blocks {38}, there are excellent automated tools, often based on simulated annealing {33} coupled with a floor plan representation scheme such as sequence pair {39}. For representing a floor plan with n macro blocks, the sequence pair approach uses two arrays, each placing the n blocks in some order. If, in the two arrays, block bi is before block bj, this indicates that bi is “to the left” of bj. If bj is before bi in the second array, this indicates bi is “below” bj. This relative positioning relationship can be utilized to find any possible floor plan. With annealing, and for relatively small problems, excellent floor plans can be obtained.

At the other end of the placement spectrum is standard cell design. Millions of circuit elements-simple “and” and “or” gates, for example—must be arranged in a way that minimizes interconnect length. By using a uniform height for each cell, the packing of logic elements becomes much easier; cells are arranged in rows, and typically there is enough extra space available such that legal solutions are easy to find.

For a design that contains a large number of standard cells, there are excellent tools that use simulated annealing, recursive bisection (for example {40}), or analytic methods (for example, {41}).

Handling both large macro blocks and large numbers of standard cells simultaneously, is uncommon. More often, a design team will first place the macro blocks with extensive manual guidance, and then use automated tools (most often based on analytic approaches) to fill in the standard cells between the macro blocks.

### Graph Partitioning

Theoretical computer science has shown that for a great many problems of practical interest are in some sense “equivalent” {37}. Problems such as Boolean satisfiability, finding a subset a set of numbers to sum to a particular total, or finding a Hamiltonian cycle in the graph are all “NP-Complete,” with no known polynomial time algorithms.

Most areas of circuit design hinge on finding solutions—at least good solutions if not optimal ones—to a variety of inter-related NP-Complete problems. For circuit placement, first a two-dimensional packing problem is faced. If that can be solved, a facility-location type of problem is faced. The placement leads to a host of routing problems, and lurking all the time is the longest critical path problem if seeking to optimize circuit performance. Before circuit placement begins, and all the way through manufacturing, there are hurdles and road blocks that must be overcome.

Lacking any chance of finding an optimal solution, there is a practical interest in finding the best available solution. In the abstract, an objective function ƒ, which depends on variables v1, v2, . . . , vn, with the variables often being integer is presented. For some types of problems, finding a maximal or minimal value for ƒ is trivial; within circuit design, most of the interesting problems are intractable.

Graph partitioning is one of the “classic” NP-complete problems. Most researchers working on optimization know that current heuristics are quite good, but this point should be emphasized—modern partitioners such as hMetis {42} are truly exceptional, and have ideas that can and should be more broadly utilized.

### The Partitioning Solution Space

To provide more insight into the operation of modern partitioners, consider FIGS. 2A and 2B, a simple partitioning problem for a graph with two vertices. The solution space for the problem consists of four different possible configurations; the number of edges cut has been annotated onto the nodes in the solution space.

What makes the partitioning problem “hard” is that there can be a great many local minima in the solution space. FIG. 3, taken from {43}, shows a simple graph with twelve nodes, partitioned with a cut of four. Moving any single vertex (or a pair of vertices) from one side to another does not reduce the cut, even though there is an “obvious” optimal solution. This is the challenge for partitioning methods—there is no way to know if there is a solution that is better than a “current” one, or which vertex to move in order to find such a better solution.

The size of the solution space grows exponentially with the number of vertices sought to be partitioned; in FIG. 4, the solution space for a graph that might have eight vertices is shown. There are 2⁸ possible configurations, (2⁸) 4 edges, and there can be a great many local minima. Even for trivially small graphs, this can be overwhelming.

### Hill Climbing

In contrast to “easy” optimization problems—such as would be handled by methods such as Simplex-combinatorial optimization problems such as partitioning require hill climbing to escape local minima. FIGS. 5A and 5B illustrate the notion; for Simplex, one can simply check the local gradients, and move towards a globally optimal solution. With discrete values for variables, and a more complex objective function, the cost surface has stair-step discontinuities, and higher cost solutions are passed through to find a lower cost configuration elsewhere. The two-dimensional representation in FIGS. 5A and 5B hide the complexity—the solution space is vast and complex, with many possible “directions” to go, as indicated in FIG. 4.

The popularity of simulated annealing comes from it's excellent hill climbing capabilities. By allowing “uphill” moves (probabilistically), the optimization process can escape a local minima.

One of the earliest effective partitioning heuristics by Kernighan and Lin {34} (generally referred to as “KL”) also performs hill climbing, by repeatedly swapping pairs of vertices, and then locking them in place. The heuristic operates in multiple passes—unlocking all vertices, and then proceeding until all vertices have switched sides. If one examines the “cut” metric during a pass, there are many times where a swap will increase cost—only to have the heuristic climb over a hill, and then descend into a better “valley.”

In an early study of partitioning algorithms, Johnson {43} compared simulated annealing to the KL heuristic on a set of small graphs. For a geometric graph with 500 vertices, the annealing approach had an average cut of 213.32, while KL averaged 232.29—giving the advantage to annealing if given the same number of runs. KL, however was substantially faster; with equalized run times, the gap narrows significantly. Both annealing and KL were substantially better than local optimization methods, showing the value of hill climbing.

### Efficient Data Structures

A major leap in the speed of partitioning heuristics is due to Fiduccia and Mattheyeses {35}. A clever gain bucket strategy, coupled with movement of a single vertex at a time, brought the computational complexity of a single optimization pass down to O(n), versus O(n²) or even O(n³) for KL (depending on implementation details). This speedup did not degrade quality significantly.

A single pass of the “FM” heuristic is illustrated in FIG. 6. Beginning with an initial partition, a single vertex is shifted to “the other side” and locked in place. The shifting is greedy—the vertex moved either reduces the cut as much as possible, or increases it minimally. As with KL, the “uphill” moves are essential to escape a local minima. The “FM” heuristic starts with an initial partition, and ends with a mirror image. After moving all vertices, a pass “rolls back” to the best configuration found—this is essentially a series of moves of vertices from one side to another, followed by the remaining vertices opting for “don't move.”

In FIG. 6, both the entire solution space (for a graph with five vertices), as well as the complete binary tree are shown. The technology may also be applied to other graph partitioning problems.

### Modern Multi-Level Partitioning

Partitioners took a dramatic leap in performance, with the introduction of multi-level clustering. A single level of clustering was introduced by Cong and Smith {44}, and this was extended in the well-known hMetis package from Karypis {42}. The magnitude of advancement should not be overlooked.

As ISPD 1998, Alpert {45} presented a series of partitioning benchmarks derived from industrial circuit designs. Using a variety of partitioning approaches, the dominance of multi-level partitioning becomes obvious; Table 1 summarizes this.

### Quality Enhancing Subspaces

If one views multilevel partitioning from a slightly different perspective, it becomes clear that the core techniques can be applied to a broader class of problems.

The effect of the clustering step is to constrain the solution space-every possible configuration in the solution space of a clustered graph maps directly onto a possible configuration of the original unclustered solution space. Referring back to FIG. 4, the solution space is a direct subset.

An important but perhaps overlooked aspect is the impact of the clustering on the average cut sizes. While it's impossible to find the true average (there are simply too many combinations), an approximate value can be determined by sampling random partitions.

In Table 2, show the average cuts of random partitions for the IBM01 graph are shown, and then the cuts as a relatively simple clustering heuristic is applied. The “flat” graph has an average cut over 9000; as clustering is repeatedly applied, the average cut drops to less than a third of the initial value.

Not only are the clustered graphs smaller—the typical cuts within the clustered graphs are also lower, making it easier for the FM heuristic to find a good solution. It is easier to climb over a hill if you remove a mountain sitting on top of it.

### Mixed-Size Placement

As noted, the typical design flow for industrial circuits is to perform floor planning manually, followed by standard cell placement. Because of this, there were relatively few mixed size placement benchmarks. Roughly twenty years ago a number of groups in academia sought to address this topic.

Using the partitioning benchmarks from Alpert {45}, in 2002 Adya created the IBM Mixed Size benchmarks {46}, with the research group utilizing a number of different approaches. This group of benchmarks is shown in Table 3.

With a fast and effective partitioning algorithm, it is possible to create a surprisingly fast and effective mixed size placement approach using a recursive bisection based framework. The feng shui placement tool {47}, published in 2004, essentially ignored the size differentials between objects, relying on the hMetis partitioning algorithm to deal with the macro blocks. With a simple variation of Hill's “tetris” legalization scheme {48}, feng shui found high quality placements. Results of the approach are shown in Table 4.

Following the improvements with recursive bisection, analytic placement methods also advanced, gaining better ability to support both large and small objects. Later in 2004, the Aplace {41} improved on the results of feng shui for a subset of the benchmark suite. On the ten smallest designs, a wire length reduction of about 1% was obtained. In the following year, the tool Uplace {51} was able to find results within a few percentage points of feng shui, also using only the ten smallest benchmarks from the set. These results are shown in Table 5.

Following the initial set of mixed size benchmarks based on the ISPD partitioning benchmarks, a variety of new designs were considered. In Table 6, experiments performed by Ng {52} on a set of designs with large rectangular blocks are shown. Lacking any ability to rotate blocks, and poor handling of blocks that were not square, feng shui showed pathological worst-case behavior, while the scampi approach of the authors fared well. These benchmarks are summarized in Table 6.

While there were a small number of groups working with mixed-size placement, industry focus remained on placement with fixed macro blocks. For the ISPD placement contests {53} in 2005 and 2006, the benchmarks featured large numbers of fixed blocks, and a great deal of open area “white space.” Results from the 2005 contest are shown in Table 7; while the bisection based approach of feng shui was competitive with the analytic tool Aplace for mixed size benchmarks with movable macro blocks, Aplace far outpaced bisection for the fixed block designs. FIGS. 7A and 7B show two placements for one of the benchmarks; the analytic approach was able to shift the cells between the fixed macro blocks, obtaining low interconnection length. The bisection approach, by contrast, treated the macro blocks as obstacles, and was unable to utilize the open space effectively.

Placement research focusing on the ISPD2005/2006 contest benchmarks has continued—including a number of efforts where the fixed benchmarks are marked as movable {54, 55}

Extending the Techniques from Multi-Level Partitioning

There is considerable interest in machine learning techniques, in part because it is “new,” and may be applicable to a range of problems that were previously handled poorly. While new techniques are always welcome, “old techniques” can also be applied in new ways.

The formulation shown in FIG. 6 can be applied on to any combinatorial problem—if a set of variables with discrete values is presented, a brute-force tree could enumerate the entire solution space (and would thus contain the optimal solution). The “locking” of variables, and forced changes of a pass of FM, allow partitioning heuristics to climb out of local minima, finding better solutions.

The clustering of multi-level methods reduce the size of the solution space—and importantly, remove a great many “bad” configurations, making it easier to pass from one “good” solution to another.

These key ideas can be applied to problems that look nothing like partitioning. For example, the detailed placement engine within the current version of feng shui utilizes the partitioning-style hill climbing approach {56}. For windows that can have hundreds of standard cells, detailed placement seeks to rearrange the cells to minimize interconnect length.

By restricting cells to their original rows, the solution space becomes much smaller—but also, the wire lengths of any particular arrangement become much better on average. This has the same effect as clustering—but not clustering is required. A “second level” optimization is to restrict the types of permutations considered-again, dramatically reducing the size of the solution space, while improving the average quality of the solutions represented.

The method in {56} searches the solution space in brute-force manner, but prunes based on incremental cost at each level of the search tree. Because on each level, the same set of cells have been permuted in the same areas, a degree of comparability can be established between branches—this again aids the search.

Across a wide range of designs, the detailed placement approach obtained wire length gains over traditional methods, while also having near linear run times.

Another variation of these ideas can be seen in the global routing tool HydraRoute {57}. In this work, the potential solution space was reduced from “any possible route between a pair of points,” to a small set of single or dual bend configurations. Having only a small number of potential routes for each connection allowed for a preprocessing step to detect quickly potential conflicts between routes. The routing process then proceeded in breadth-first manner, similar to both FM and the detailed routing approach, with pruning to limit the size of the solution space.

There is perhaps an expectation that to do well in optimization, every possibility must be available. Constraining the solution space, whether by clustering, limiting the rows for assignment to a standard cell, or the types of routes considered for a net, can make the problem more tractable. In this restricted solution space, a simple tree search such as by FM, or by pruned breadth-first approach, can be extremely effective.

### Mixed-Size Placement Tools

Given the number of research groups actively working on mixed size placement over the years, and the number of benchmark suites created, a natural question might be why is automated mixed size placement uncommon?

When considering the objectives of a design team, the motivations become more clear. Most design teams seek to maximize performance, while minimizing risk. To achieve this, the design of a large circuit is handled in an iterative process—an initial layout is examined carefully, critical paths and performance issues are identified, and then a new design is created.

Having stability in the design process is essential for convergence {58}. If the locations of circuit elements move dramatically, critical paths will change as well—and then any effort in circuit optimization will be lost, and the design team will need to “start from scratch” a second time.

By fixing the locations of the large macro blocks, a design team can introduce a great deal of stability. An analytic placer, using the macro blocks as anchors, will repeatedly converge to similar placement solutions if the changes to the net list are minor.

In many respects, analytic placement tools are an ideal fit for current design practices—and current design practices are optimized to take advantage of the tools that support them best. This is a reinforcing cycle, and without a dramatic push to change methodology, it is reasonable to expect that most design teams will continue the manual placement of large blocks, with analytic methods to handle the large numbers of standard cells.

While new methods are always welcome, old methods also have a great deal to offer. The hill climbing and clustering ideas found in multi-level partitioners merit much more attention.

For the mixed-size placement problem, it has been studied for many years—and that despite the effort, full automation has not become part of current design practices. Stability and predictability are key concerns for design teams; fixed macro blocks, even if they require manual effort, provide this.

There is also no clear “best way forward” for mixed size design. Depending on the benchmark suite, one approach may vastly outpace another. It is also not uncommon for a benchmark to trigger pathological worst-case behavior in some tools. For floor planning with small numbers of large blocks, annealing seems to have an edge. With movable macro blocks (provided they are not extremely large), recursive bisection has fared well. With many large movable macros, a floor-placement perspective seems appropriate. When macro blocks are fixed, analytic placement tools excel.

Initial results for mixed size placement with reinforcement learning {36} are interesting, but hard to evaluate. Experiments in this first paper utilize proprietary circuits, preventing easy comparisons with other approaches. A subsequent publication {59} reports results on other benchmarks, but these appear to be derived from detail routing driven placement work {60}, and not the widely used ISPD “Adaptec” and “Big Blue” mixed size benchmarks {61}.

No matter what the design methodology, public benchmarking is critical {62}. Benchmarks allow different approaches to be compared, and can often highlight elements that cause an approach to succeed or fail in spectacular manner. Benchmarks, and consistent performance, can also give circuit designers confidence in new methodologies.

Khatkhate et al. {28} and {29} discuss an effective automated way to place macro blocks and standard cells simultaneously. However, this was not generally adoption by industry. This method had deficits in handling fixed macro blocks. In 2020, Google presented a machine learning based tool to do macro block placement. {30} The paper provides no experimental results. An analysis of this work is discussed in {31}. See also {32}.

However, the application of machine learning to the macro block placement problem is not untenable.

The present technology employs recursive bisection. According to this technology a recursive bisection based placement tool is provided to handle mixed block designs with standard cell and macro block placement handled concurrently.

In standard cell placement, a large number of cells, which are small rectangular blocks that are of uniform height, but possibly varying width, are provided. Each cell contains the circuitry for a relatively simple logical function, and the cells are packed into rows much as one might use bricks to form a wall. The desired circuit functionality is obtained by connecting each cell with metal wiring. The arrangement of cells is critical to obtaining a high performance circuit. Due to the dominance of interconnect on system delay {9}, slight changes to the locations of individual cells can have sweeping impact. Beyond simple performance objectives, a poor placement may be infeasible due to routing issues: there is a finite amount of routing space available, and a placement that requires large amounts of wiring (or wiring concentrated into a small region) may fail to route. Well known methods for standard cell placement include simulated annealing {23, 26}, analytic methods {15, 11}, and recursive bisection {7, 4}.

Block placement, block packing, and floorplanning {19} problems involve a small number of large rectilinear shapes. There are usually less than a few hundred shapes which are almost always rectangular. Each block might contain large numbers of standard cells, smaller blocks, or a mix of both; the internal details are normally hidden, with the placement tool operating on an abstracted problem.

For blocks, we must arrange them such that there is no overlap; the optimization objective is generally a combination of the minimization of the amount of wasted space, and also a minimization of the total routing wire length. Small perturbations to a placement (for example, switching the orientation of a block, or swapping the locations of a pair of blocks) can introduce overlaps or change wire length significantly; simulated annealing is commonly used to explore different placements, as it is effective in escaping local minima. There are a number of different floorplan and block placement representation methods {18, 17, 1, 20}, each having different merits with respect to the computational expense of evaluating a placement.

Between the extremes of standard cell placement and floorplanning, is mixed block design. Macro blocks of moderate size are intermixed with large numbers of standard cells. The macro blocks occupy an integral number of cell rows, and complicate the placement process in a number of ways. If a block is moved, it may overlap a large number of standard cells—these must be moved to new locations if the placement is to be legal. The change in wire length for such a move can make the optimization cost function chaotic. There is also considerable computational expense in simply considering a particular move.

Early researchers {24, 25, 22, 21} used a hierarchical approach, where the standard cells were first partitioned into blocks using either a logical hierarchy or min-cut-based partitioning algorithms. Floorplanning was then performed on the mix of macro blocks and partitioned blocks, with the goal (objective) of minimizing wirelength. Finally, the cells in each block were placed separately using detailed placement. While this method reduces problem size to the extent where the floorplanning techniques can be applied, pre-partitioning standard cells to form rectangular blocks may prevent such a hierarchical method from finding an optimal or near-optimal solution.

The Macro Block Placement program {25} restricts the partitioned blocks to a rectangular shape. However, using rectilinear blocks are more likely to satisfy high performance circuit needs. The ARCHITECT floorplanner {22} overcomes this limitation and permits rectilinear blocks.

Mixed-Mode Placement (MMP) {27} uses a quadratic placement algorithm combined with a bottom-up two-level clustering strategy and slicing partitions to remove overlaps. MMP was demonstrated on industrial circuits with thousands of standard cells and not more than 10 macro blocks.

A three stage placement-floorplanning-placement flow {2, 3} was presented to place designs with large numbers macro blocks and standard cells. The flow utilizes the Capo standard cell placement tool, and the Parquet floorplanner. In the first stage, all macro blocks are “shredded” into a number of smaller subcells connected by two-pin nets created to ensure that sub-cells are placed close to each other during the initial placement. A global placer is then used to obtain an initial placement. In the second stage, initial locations of macros are produced by averaging the locations of cells created during the shredding process. The standard cells are merged into soft blocks, and a fixed-outline floorplanner generates valid locations for the macro blocks and soft blocks of movable cells. In the final stage, the macro blocks are fixed into place, and cells in the soft blocks go through a detailed placement.

This flow is similar to the hierarchical design flow as both use floorplanning techniques to generate an overlap-free floorplan followed by standard cell placement. Rather than using pure partitioning algorithms to generate blocks for standard cells, this flow proposes to use an initial placement result to facilitate good soft block generation for standard cells. While this approach scales reasonably well, our experimental results show that it is not competitive in terms of wire length.

A different approach is pursued in {8}. The simulated annealing based multi-level optimization tool, mPG, consists of a coarsening phase and a refinement phase. In the coarsening phase, both macro blocks and standard cells are recursively clustered together to build a hierarchy. In the refinement phase, large objects are gradually fixed in place, and any overlaps between them are gradually removed. The locations of smaller objects are determined during further refinement. Considerable effort is needed for legalization and overlap removal; the results of mPG are superior to those of {3}, they are also not competitive with the results of Khatkhate et al.

{28} proposes a mixed block placement approach based on recursive bisection. The high level approach is summarized as follows:
Partition the circuit using “Fractional Cut” based recursive bisection.
Remove overlaps using Greedy Legalization technique.
Perform branch and bound reordering on standard cells.

The basic recursive bisection method is well known and uses the multi-level partitioner hMetis {14}: a partitioning algorithm splits a circuit netlist into two components, with the elements of each component being assigned to portions of a placement region. The partitioning progresses until each logic element is assigned to its own small portion of the placement region. Placement tools which follow this approach include {6, 10, 7, 4}.

Traditionally, the placement region is split horizontally and vertically, with all horizontal “cuts” being aligned with cell row boundaries. In {4}, the placement tool introduced a fractional cut approach; this was used to allow horizontal cut lines that were not aligned with row boundaries. Instead of row-aligned horizontal cuts, the partitioning solution and region areas were determined without regard to cell row boundaries. After completion of the partitioning process, cells were placed into legal (row aligned and non-overlapping) positions by a dynamic programming based approach.

When bisecting a region, the area of each region must match the area of the logic elements assigned to it, but there is no constraint that the shape of the region be compatible with the logic. For example, it is possible to have a region that is less than one cell row tall. While the logic elements can overlap slightly during bisection, the area constraints ensure that there is enough “space” in the nearby area such that the design can be legalized without a large amount of displacement.

The standard fractional cut based bisection process is adapted in {28} to simply ignore the fact that some elements of the net list are more than one row tall. Rather than adding software to handle macro blocks, the source code is modified to not distinguish between macro blocks and standard cells. The partitioning process proceeds in the same manner as most bisection based placement tools. The net list is partitioned until each region contains only a single circuit element. The area for each region matches the area of the circuit element that it contains-if the element happens to be a macro block, the area is simply larger than another region that might hold a standard cell. The output of the bisection process is a set of “desired” locations for each block and cell; as with analytic placement methods, these locations are not legal, and there is some overlap. Fortunately, the amount of overlap is relatively small (due to area constraints and the use of fractional cut lines), allowing legalization to be performed with relative case.

The Feng Shui 2.0 placement tool {4} used a dynamic programming-based legalization method. The legalization process operated on a row-by-row basis, selecting cells to assign to a row. As macro blocks span multiple rows, this method could not be used directly. A first attempt at a legalization method used a recursive greedy algorithm, which attempted to find good locations for the macro blocks in the core region, fixing them in place, and then placing the standard cells in the remaining available space. A block was considered to be legal if it was inside the core region and did not overlap with any of the previously placed blocks. Blocks were processed one at a time; if the block position was acceptable, the location was finalized. If the block position was not acceptable, a recursive search procedure ensued to find a nearby location where the block could be fixed into place. After fixing the block locations, the standard cell rows were “fractured” to obtain space in which the standard cells could be placed. A modified version of the dynamic programming method presented in {4} was used to assign standard cell locations. For designs with relatively few blocks, or blocks that were uniformly distributed in the placement region, our initial approach worked well. However, for the designs with many macro blocks, the large numbers of overlaps caused this approach to fail.

An algorithm presented in a technical report by Li {16}, comparable to an earlier method patented by Hill {13} gave good performance. The method by Hill can handle only objects with uniform height; {28} improved on this method to allow legalization of designs with both standard cells and macro blocks. For standard cell design, the method by Hill uses a simple greedy approach. All cells are sorted by their x coordinate; each cell is then packed one at a time into the row which minimizes total displacement for that cell. To avoid cell overlaps, the “right edge” for each row is updated, and the packing is done such that the cell being inserted does not cross the right edge. The patent describes packing from the left, right, top, or bottom, for objects that are either of uniform height or uniform width. {28} removed the need for uniform height or width, and all circuit elements are sorted by their desired x coordinate, and assignment is performed in a greedy manner. Macro blocks are considered simultaneously with standard cells; the “right edge” checking is enhanced to consider multiple rows when packing a macro block. This method is outlined in Algorithm 1.

Algorithm 2 Greedy legalization; circuit elements are processed one at a time, with each being assigned to the row that gives a minimum displacement.

### Algorithm 1

```
Sort all cells/macros by their “left edge” locations.
for each row r do
  right_edge [r] lx[r];
end for
for each cell/macro c do
  llx[c] legal_x (lx[c]);
  for each row r do
    if macro crosses upper/lower boundary then
      continue;
    end if
    if llx[c] < right_edge [r] then
      dx = Di ff (lx[c], right_edge [r];
    else
      dx =Di ff (lx[c], llx[c]);
    end if
    dy = Di ff(ly[c], ly[r];
    cost = COST(dx, dy);
    Store best_cost, best_llx, best_row.
  end for
  llx[c] =best_llx;
  row[c] = best_row;
end for
```

The macro blocks are treated very much like standard cells; they must be placed at the end of a growing row, and not overlap with any placed cell. The introduction of multi-row objects can result in “white space” within the placement region. Assuming that there are a number of nearby standard cells, the “liquidity” of the placement allows the cells to flow into the gaps, resulting in a tight packing while considering both blocks and cells simultaneously.

However, for some designs, the greedy legalization method initially failed to place all blocks within the core area. The fractional cut representation created regions that did not match the shape of the actual blocks, resulting in them “stacking” during the greedy legalization step. This was addressed by an enhancement Algorithm 2:

Algorithm 2 Improved greedy legalization. For some circuits, macro block overlaps resulted in a horizontal arrangement that exceeded the core width. By reducing cost, the penalty of shifting blocks vertically, we obtain placements that fit within the core area.

### Algorithm 2

```
done = 0;
Initialize “ycost”.
while !done do
  done = 1;
  for each cell/macro do
    greedy_legalize( );
    if cell crosses right boundary then
      Decrease ycost.
      done = 0;
      break;
    else
      Store best solution.
    end if
  end for
end while
```

If the legalization results in circuit elements being placed outside of the core region, the penalty for displacing a cell or macro block in the vertical direction is gradually reduced. During legalization, rather than shifting blocks horizontally (creating a “stack”), the reduced vertical displacement penalty results in blocks and cells moving up or down to find positions in rows that are closer to the left side of the placement region. While this generally increases the total wire length, it allows all benchmarks to be legalized within the allowed core area.

Following legalization, a window-based branch-and-bound detailed placement step is performed. Macro blocks are not moved during this step, and only a small number of standard cells at a time are considered, with all orderings enumerated to find an order which minimizes wire length. Thus, to summarize approach of {28}, a number of fairly simple techniques are employed to obtain good results. The basic placement framework is traditional recursive bisection, with a fractional cut representation. The difference between standard cells and macro blocks is essentially ignored during bisection, and only the total area considered. Following bisection, a very simple greedy legalization technique is applied. Detailed placement is performed with traditional window-based branch-and-bound. The legalization method does not perform the deliberate insertion of “whitespace,” so designs may be somewhat more dense than those of Capo or mPG.

Vannelli, A., & Hadley, S. W. (1990). A Gomory-Hu cut tree representation of a netlist partitioning problem. IEEE Transactions on Circuits and Systems, 37 (9), 1133-1139. doi: 10.1109/31.57601 discuss a tree cut method for netlist analysis. The method consists of approximating a netlist, which can be represented as a hypergraph, by an undirected graph with weighted edges. A Gomory-Hu cut tree is formed from the resulting undirected graph. A Gomory-Hu cut tree allows one to generate netlist partitions for every pair of modules and estimate how far this netlist cut is from optimality. The issue addressed is to disconnect modules (gates or arrays) connected by wires (nets or signals) into two blocks of modules such that the number of wires cut is minimized.

Vanelli et al. approximates a netlist, which can be represented as a hypergraph, by an undirected graph with weighted edges. Second, the Gomory-Hu algorithm {R. E. Gomory and T. C. Hu, “Multi-terminal network flows,” J. SUM, vol. 9, no. 4, pp. 551-570, 1961.} is used on the resulting undirected graph to find a cut tree where the minimum cut separating any pair of modules can be determined. Lawler {E. L. Lawler, “Cutsets and partitions of hypergraphs,” Networks, vol. 3, pp. 275-285, 1973.} develops a generalized maximum flow algorithm for finding the minimum netlist partition that separates a fixed pair of modules only. To find the minimum netlist partition separating all module pairs using this algorithm would require the solution of n (n−1)/2 maximal flow problems (assuming the netlist contains n modules). If n is large, this approach can become computationally expensive.

By approximating the netlist by a weighted graph and using the Gomory-Hu algorithm, at most, (n−1) maximum-flow/minimum-cut evaluations are required to find good netlist partitions for any subset of the n modules. The resulting weighted undirected graph cut is a lower bound separating the netlist cut of a given pair of modules. Finally, a netlist cut is determined by analyzing the edges of the cut tree whose removal separates the modules into two blocks.

The most important VLSI design feature of this method is that it allows the designer to consider a variety of module groupings by looking at the Gomory-Hu cut tree connecting the modules. The designer can analyze the quality of the cut by estimating how far this cut is from optimality. Other aspects such as block size can also be considered at the same time.

### SUMMARY OF THE INVENTION

There are multiple forces which have prevented full automation in floor planning of integrated circuit designs. A lack of algorithmic methods is not the only factor that has impeded automation. There are a number of “traditional” methods that should be reconsidered. Recursive bisection is one such technique. Sec, Mohammad Khasawnch and Patrick H. Madden. 2022. What's So Hard About (Mixed-Size) Placement?. In Proceedings of the 2022 International Symposium on Physical Design (ISPD '22), Mar. 27-30, 2022, Virtual Event, Canada. ACM, New York, NY, USA, 8 pages. doi.org/10.1145/3505170. 3511035

While solving balanced bi-partition graph partitioning optimally is NP-Complete, a number of advances over the years have produced an approach that is effective, with near linear-time performance. Using this partitioning approach, placement for designs that contain both macro blocks and standard cells is facilitated, thus addressing the “mixed size” or “boulders and dust” placement problem.

It is therefore an object to provide a method of laying out an integrated circuit, and a system therefor, comprising: receiving or defining a netlist of a plurality of macro blocks and cells of the integrated circuit; repeatedly or recursively partitioning the netlist using bisection, using a set of multi-level partitioning heuristics, to produce a cut tree set for each partitioning; defining a plurality of regional arrangements of the macro blocks and cells utilizing the cut trees generated during repeated partitioning; legalizing the plurality of regional arrangements using dynamic programming to rectangular regions that match a size of a region produced by the bisection; and merging the legalized bisected regions of a respective tree to generate a set of potential placements.

It is also an object to provide a method of laying out an integrated circuit, comprising: defining a netlist of circuit elements comprising a plurality of macro blocks and standard cells of the integrated circuit, and associated kernel graphs, each macro block and standard cell having a respective area requirement; obtaining a hierarchical abstract relative positioning of the circuit elements, and associated kernel graphs, within a hierarchy of regions, by at least one of repeatedly partitioning the netlist using bisection, and inducing cut lines into an abstract placement generated by an analytic placement tool; storing the hierarchical abstract relative positioning of the circuit elements (SHARP); defining a plurality of arrangements of the macro blocks and standard cells within a respective region utilizing the SHARP; iteratively legalizing the plurality of arrangements of the macro blocks and standard cells, and the associated kernel graphs, within the respective region to form legalized regions, using a plurality of legalization techniques for each respective arrangement, each legalized region meeting the area requirements of the circuit elements within each respective region, wherein in each iteration of the legalization, at least a portion of the SHARP of the circuit elements is reused; and merging the legalized regions to generate a set of potential placements.

The hierarchical abstract relative positioning of the circuit elements may be obtained by repeatedly partitioning the netlist using bisection.

The method may alter an aspect ratio of a bisected region, within limits imposed by macro blocks and required wiring peripheral to the macro blocks and cells, for at least one bisected region. Cells within the bisected region are therefore relocated according to a desired aspect ratio and various other constraints, such as performance, feasibility, etc. The aspect ratio alteration may be focused on bisected regions without macro blocks, providing increased freedom of relocation. Where a macro block is present, it will often dominate the bisected region, limiting efficiency gains available through the alteration.

The hierarchical abstract relative positioning of the circuit elements may be obtained by inducing cut lines into an abstract placement generated by an analytic placement tool.

The cut tree sets may be pruned using pareto optimization.

The method may select at least one set of potential placements, wherein at least one of the bisecting and selecting is performed using a trained neural network.

The method may further comprise comparing performance-related characteristics of the potential placements, and selecting a potential placement according to the compared performance-related characteristics.

The legalizing of the plurality of regional arrangements may be performed using dynamic programming, wherein the dynamic programming is used to perform kernel selection and mapping.

A kernel graph may be traversed from inputs to outputs, in breadth-first order, and the order in which kernels are encountered by traversal is selected as the order in which to place kernels across the layout.

A non-dominated subset of potential placements may be determined using Bentley's divide and conquer algorithm.

Non-dominated horizontal sequential subsets of kernels may be determined with the dynamic programming, wherein the non-dominated horizontal sequential subsets of kernels are arranged as strips. The strips may be stacked into horizontal rows using dynamic programming. Alternate strips may be disposed in reverse order, to create a serpentine pattern.

The cut trees may be pruned according to a feasibility criterion and/or a performance characteristic.

The method may further comprise, for at least one bisected region that does not comprise exclusively macro blocks: altering an aspect ratio of the bisected region that does not comprise exclusively macro blocks; and altering contained macro block and standard cell positions within the bisected region that does not comprise exclusively macro blocks based on the altered aspect ratio.

The respective region may be rectangular, and the method further comprise altering an aspect ratio of a bisected respective region while meeting the respective area requirement of a macro block, and altering standard cell positions within the altered aspect ratio bisected respective region.

The hierarchical abstract relative positioning of the circuit elements may comprise a tree, and the obtaining of the hierarchical abstract relative positioning of the circuit elements within the hierarchy of regions may comprise inducing cut lines in the tree to produce a cut tree. The method may further comprise pruning the cut tree sets using pareto optimization. The cut trees may be pruned according to at least one of a feasibility criterion and a performance characteristic.

The method may further comprise performance-related characteristics of the potential placements; and selecting a potential placement according to the compared performance-related characteristics.

The method may further comprise annotating or altering a SHARP with netlist and circuit element changes dependent on a performance optimization of a circuit according to a respective legalized region.

The method may further comprise: modifying a size of a respective circuit element; and defining a second plurality of arrangements of the modified size respective circuit element within a respective region re-utilizing at least one SHARP. The iteratively legalizing may comprise legalizing the second plurality of arrangements of the macro blocks and standard cells within the respective region and associated kernel graphs to form second legalized regions, and the second legalized regions are merged to generate a second set of potential placements.

The method may further comprise annotating or altering a SHARP by replacing a macro block with a SHARP that represents an internal structure of the macro block, wherein the SHARP that represents an internal structure of the macro block relieves the respective area requirement of the macro block.

The plurality of arrangements of the macro blocks and standard cells within the respective region may be legalized using dynamic programming. The dynamic programming may perform kernel selection and mapping.

A respective kernel graph may be traversed from inputs to outputs, in breadth-first order, and the order in which kernels are encountered by traversal is selected as the order in which to place kernels across the layout. A non-dominated subset of potential placements may be determined using Bentley's divide and conquer algorithm. Non-dominated horizontal sequential subsets of kernels may be determined with dynamic programming, and the non-dominated horizontal sequential subsets of kernels arranged as strips. The strips may be stacked into horizontal rows using dynamic programming. Alternate strips may be disposed in reverse order, to create a serpentine pattern.

It is a still further object to provide a system for laying out an integrated circuit, comprising: an input configured to receive a netlist of circuit elements comprising a plurality of macro blocks and standard cells of the integrated circuit and associated kernel graphs, each macro block and standard cell having a respective area requirement; at least one automated processor, configured to: obtain a hierarchical abstract relative positioning of the circuit elements and associated kernel graphs, within a hierarchy of regions, by at least one of repeatedly partition the netlist using bisection, and induction of cut lines into an abstract placement generated by an analytic placement tool; store the hierarchical abstract relative positioning of the circuit elements (SHARP) in a memory; define a plurality of arrangements of the macro blocks and standard cells within a respective region utilizing the SHARP; iteratively legalize the plurality of arrangements of the macro blocks and standard cells, and associated kernel graphs, within the respective region to form legalized regions, using a plurality of legalization techniques for each respective arrangement, each legalized region meeting the area requirements of the circuit elements within each respective region, wherein in each iteration of the legalization, at least a portion of the SHARP of the circuit elements is reused; and merge the legalized regions to generate a set of potential placements; an output port configured to communicate the set of potential placements.

The at least one processor may be further configured to annotate or alter a SHARP with netlist and circuit element changes dependent on performance optimization of a circuit; and utilize the annotated or altered SHARP in a subsequent legalization.

The hierarchical abstract relative positioning of the circuit elements may comprise a tree, the hierarchical abstract relative positioning of the circuit elements within the hierarchy of regions is obtained by inducing cut lines in the tree to produce a cut tree, and the at least one processor may be further configured to assess a legalized bisected region or set of potential placements dependent on the cut tree according to at least one of a feasibility criterion, a performance characteristic, and a pareto optimization, and to prune the cut tree based the on at least one of the feasibility criterion, the performance characteristic, and the pareto optimization.

The plurality of arrangements may be legalized using dynamic programming to perform kernel selection and mapping.

It is another object to provide a non-transitory medium, storing instructions for a programmable processor for laying out an integrated circuit based on a netlist of circuit elements comprising a plurality of macro blocks and standard cells of the integrated circuit, each macro block and standard cell having a respective area requirement, comprising: instructions for obtaining a hierarchical abstract relative positioning of the circuit elements within a hierarchy of regions, by at least one of repeatedly partitioning the netlist using bisection, and inducing cut lines into an abstract placement generated by an analytic placement tool; instructions for storing the hierarchical abstract relative positioning of the circuit elements (SHARP); instructions for defining a plurality of arrangements of the macro blocks and standard cells within a respective region utilizing the SHARP; instructions for legalizing the plurality of arrangements of the macro blocks and standard cells within the respective region to form legalized regions, using a plurality of legalization techniques for each respective arrangement, each legalized region being rectangular and meeting the area requirements of the circuit elements within each respective region, wherein in each iteration of the legalization, at least a portion of the SHARP of the circuit elements is reused; and instructions for merging the legalized regions to generate a set of potential placements. The netlist may encompass kernels and/or kernel graphs, which are allocated to the macro blocks and standard cells, which are then spatially allocated together within the respective regions.

It is also an object to provides a system for laying out an integrated circuit, comprising: an input port configured to receive a netlist of a plurality of macro blocks and cells; at least one processor configured to: repeatedly partition the netlist using bisection, using a set of multi-level partitioning heuristics, to produce a cut tree set for each partition; utilize the cut trees generated during repeated partitioning to define a plurality of regional arrangements of the macro blocks and cells; legalize the plurality of regional arrangements using dynamic programming to rectangular regions that match a size of a region produced by the bisection; and merge the legalized bisected regions of a respective tree to generate a set of potential placements; and an output port configured to output at least one potential placement or placement.

The at least one processor may be further configured to alter an aspect ratio of the bisected region to an aspect ration constrained by a minimum dimension of the macro blocks and cells, and alter cell positions within the bisected region based on the altered aspect ratio.

The at least one processor may be further configured to assess a legalized bisected region or set of potential placements dependent on a cut tree set according to at least one of a feasibility criterion, a performance characteristic, and a pareto optimization, and to prune the cut tree sets based the on at least one of the feasibility criterion, the performance characteristic, and the pareto optimization.

The at least one automated processor may be further configured to partition the netlist using a first trained neural network, and select at least one set of potential placements using a second trained neural network.

The legalizing of the plurality of regional arrangements using dynamic programming may comprise using dynamic programming to perform kernel selection and mapping.

The at least one processor may be further configured to traverse a kernel graph from inputs to outputs, in breadth-first order, wherein the order in which kernels are encountered by traversal is selected as the order in which to place kernels across the layout.

It is a further object to provide a non-transitory medium, storing instructions for a programmable processor for laying out an integrated circuit, comprising: instructions for repeatedly partitioning a netlist of a plurality of macro blocks and cells using bisection, using a set of multi-level partitioning heuristics, to produce a cut tree set for each partitioning; instructions for utilizing the cut trees generated during repeated partitioning to define a plurality of regional arrangements of the macro blocks and cells; instructions for legalizing the plurality of regional arrangements using dynamic programming to rectangular regions that match a size of a region produced by the bisection; and instructions for merging the legalized bisected regions of a respective tree to generate a set of potential placements.

The non-transitory medium may further comprise instructions for altering cell positions within the bisected region to achieve an altered aspect ratio bisected region.

It is also an object to provide a method of laying out an integrated circuit, comprising: defining a netlist of a plurality of macro blocks and cells; repeatedly partitioning the netlist using bisection, using a set of multi-level partitioning heuristics, to produce a cut tree set for each partitioning; utilizing the cut trees generated during repeated partitioning to define a plurality of regional arrangements of the macro blocks and cells; legalizing the plurality of regional arrangements using dynamic programming to rectangular regions that match a size of a region produced by the bisection; and merging the legalized bisected regions of a respective tree to generate a set of potential placements.

It is also an object to provide a non-transitory medium, storing instructions for a programmable processor for laying out an integrated circuit, comprising: instructions for defining a netlist of a plurality of macro blocks and cells; instructions for repeatedly partitioning the netlist using bisection, using a set of multi-level partitioning heuristics, to produce a cut trec set for each partitioning; instructions for utilizing the cut trees generated during repeated partitioning to define a plurality of regional arrangements of the macro blocks and cells; instructions for legalizing the plurality of regional arrangements using dynamic programming to rectangular regions that match a size of a region produced by the bisection; and instructions for merging the legalized bisected regions of a respective tree to generate a set of potential placements.

For at least one bisected region that does not comprise macro blocks, an aspect ratio of the bisected region that does not comprise macro blocks may be altered, along with cell positions within the bisected region that does not comprise macro blocks based on the altered aspect ratio.

The cut tree sets may be pruned using pareto optimization.

The bisecting may be performed with a neural network.

The method may further comprise comparing performance-related characteristics of the potential placements; and selecting a potential placement according to the compared performance-related characteristics.

A placement may be selected from potential placements with a neural network.

The legalizing the plurality of regional arrangements using dynamic programming may comprise using dynamic programming to perform kernel selection and mapping.

Kernels may be split into at least two parts.

A kernel graph may be traversed from inputs to outputs, in breadth-first order. The order in which kernels are encountered by traversal may be selected as the order in which to place kernels across the layout. A non-dominated subset of potential placements may be determined using Bentley's divide and conquer algorithm.

Non-dominated horizontal sequential subsets of kernels may be determined with the dynamic programming.

The non-dominated horizontal sequential subsets of kernels may be arranged as strips, and the strips stacked into horizontal rows using dynamic programming.

Alternate strips may be disposed in reverse order, to create a serpentine pattern.

Strips may be arranged into vertical stacks.

The method may further comprise pruning the cut trees according to feasibility or performance characteristics.

### BRIEF DESCRIPTION OF THE DRAWINGS

FIG. 1 shows a floor planning with large macro blocks can be a challenging bin packing problem. In FIG. 1, a classic “wheel” organization of blocks is shown. Floor planning tools use non-trivial design representations to be able to find arrangements such as this one.

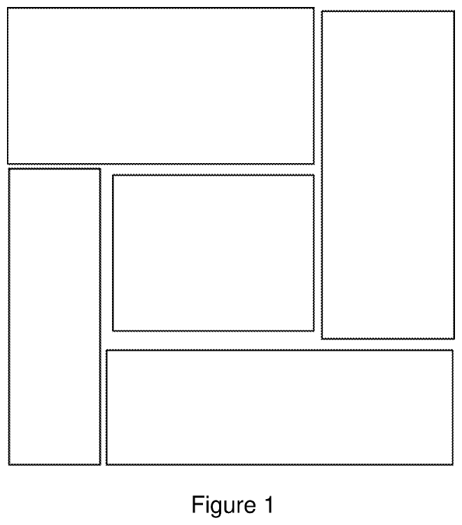

FIGS. 2A and 2B show a small graph, and the solution space of all potential partitionings. Each vertex in the solution space is labeled with the graph cut. FIG. 2A shows a simple graph to partition. FIG. 2B shows the solution space, with different potential partitionings

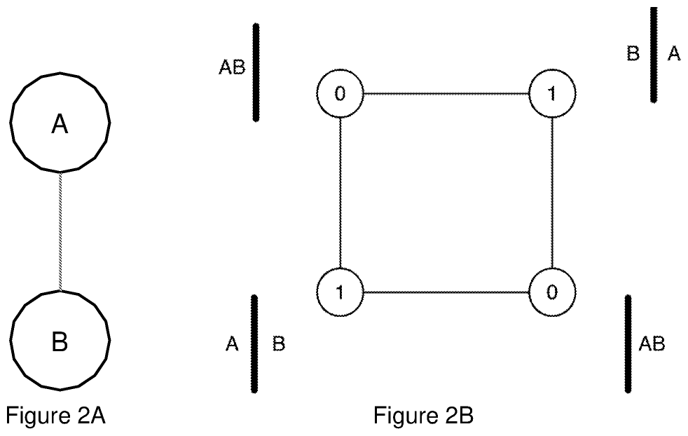

FIG. 3 shows a small graph trapped in a local minima. The cut for this configuration is four; it cannot be improved by moving a single vertex, or swapping any pair. An optimal solution (with a cut of zero) is obvious.

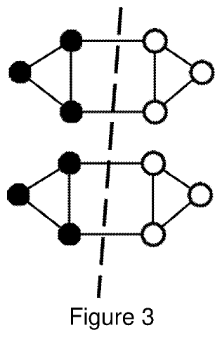

FIG. 4 shows the “solution space” for a graph with n vertices has 2n nodes; this graph is heavily connected, with each vertex has in the solution space having n possible neighbors. Any combinatorial problem can be visualized this way; each vertex in the solution space has a “cost.” Navigating this solution space to find a good (if not optimal) configuration is a fundamental problem in computer science.

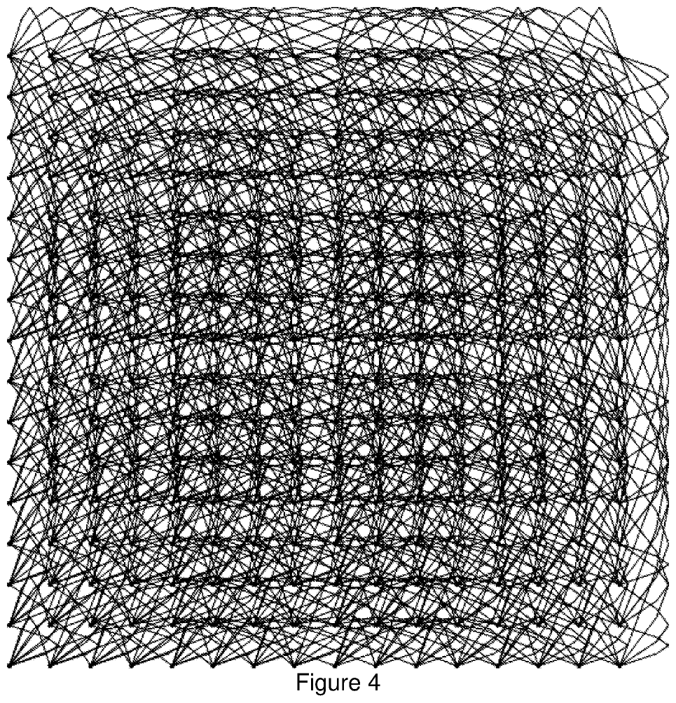

FIGS. 5A and 5B show that, for continuous optimization problems, with simple constraints and objectives such as linear inequalities, methods such as Simplex can converge on an optimal solution quickly. Problems with discrete values and more complex objectives have more challenging cost surfaces, littered with a great many local minima. FIG. 5A shows an “easy” optimization problem with linear constraints. FIG. 5B shows a “harder” optimization problem with, with many local minima.

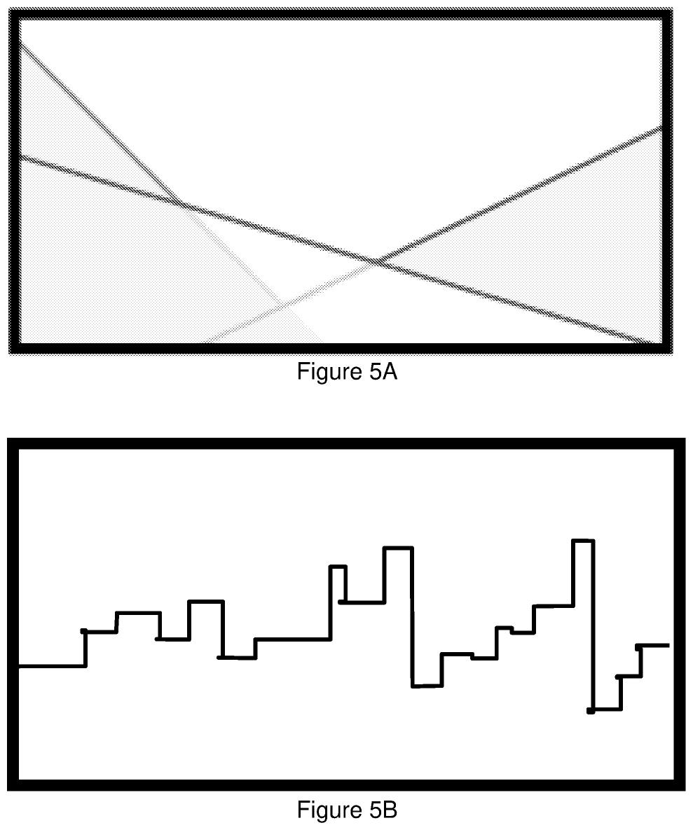

FIG. 6 shows partitioning with the Fiduccia-Mattheyses heuristic involves repeatedly moving a vertex from one side of the partition to another (with locking, and a gain minimization objective). Rolling back to the best solution observed effectively considers n configurations. In this figure, the entire solution space is illustrated, as well as a search tree that could find the optimal solution if both moving a vertex, or leaving one in place are considered.

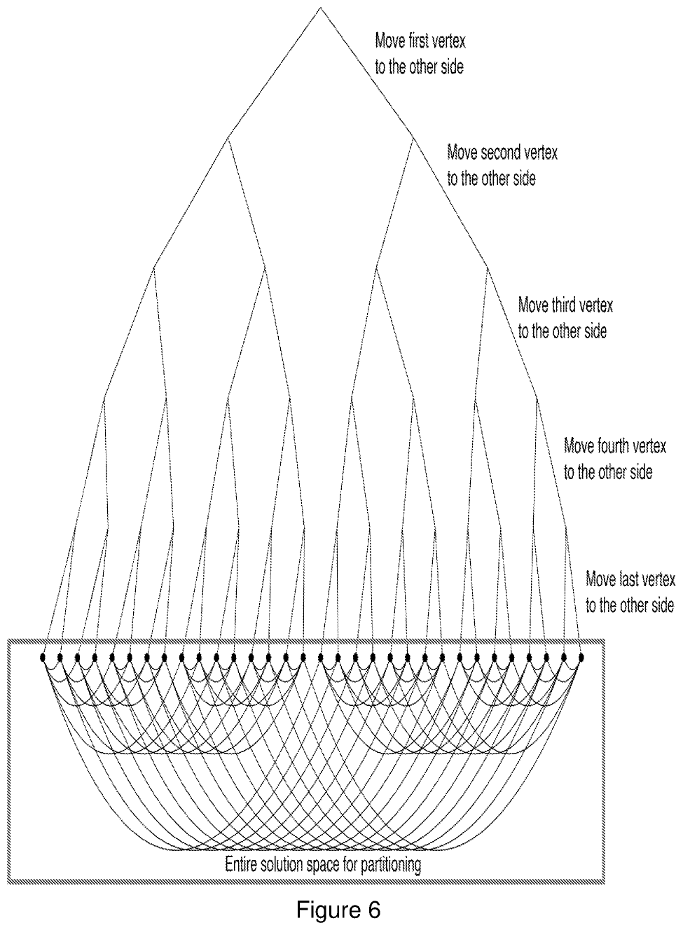

FIGS. 7A and 7B shows placements of the Adaptec2 benchmark by the tools Aplace (FIG. 7A) and feng shui (FIG. 7B). The fixed macro blocks provided anchors, allowing the analytic placement approach to converge to an excellent solution. The bisection approach of feng shui placed the cells around the macro blocks—but had no means to allocate the open space, resulting in a poor-quality solution.

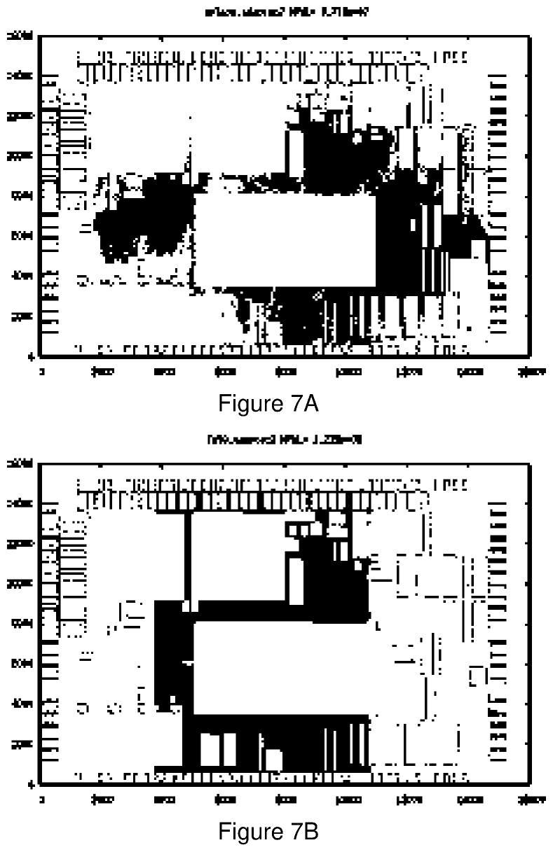

FIG. 8 shows a pseudocode model the performance of a kernel variants as part of the ISPD mapping contest. For simplicity, internal connections within each block are ignored entirely; this results in high aspect ratio blocks performing well with the contest metrics, but which would likely have poor performance in practice.

FIG. 9 shows a pseudocode for finding non-dominated packings of kernel variants as horizontal strips. Entry (i, j) holds a list of packings, for kernel kᵢ up to and including kⱼ.

FIG. 10 shows pseudocode for a dynamic programming algorithm to assemble strips of consecutive kernel variants into vertical stacks.

### DETAILED DESCRIPTION OF THE INVENTION

In integrated circuit physical design, the placement step involves finding locations for standard cells (small logic elements such as AND and OR gates), intermixed with large macro blocks (usually more complex custom-designed units). Macro blocks (typically a few dozen) are traditionally placed manually by expert human designers, while standard cells (hundreds of thousands, or millions) are placed by automated means. However, the human intuition for placement of the macro blocks is often imperfect, leading to suboptimal designs. Meanwhile, prior automated tools had their own shortcomings in terms of routability and legalization, spatial efficiency, and wire length, for example. In {28}, a recursive bisection based placement approach was described, providing simultaneous standard cell and macro block placement. This prior approach had a significant shortcoming, the loss of quality during placement legalization.

The present technology enables fast placement legalization with superior results. It also enables new methods to handle routing congestion and space demands for buffer insertion in an incremental manner. The bisection approach also supports emerging stacked-die 3D integration (multiple silicon dies physically stacked with interposer layers), optimizing multiple circuit layers, as well as designs that integrate semiconductors, MEMS, and photonic layers.

The present technology therefore employs a bisection approach to placement of macro blocks and standard cells, with consideration given to interconnections and buffers, subject to fixed and mechanical constraints. Dynamic programming may be employed. The global placement approach is recursive bisection, similar to {28}. A circuit net list is repeatedly partitioned using multi-level partitioning heuristics. The partitioned net list may then be used to provide a set of legalized placements that are ranked with respect to performance characteristics. The improvements over {28} include placement legalization. In {28}, a simple Tetris-style approach was used (handling macro blocks was an improvement over a patented approach by Dwight Hill {13}).

In contrast to the prior approach, the present technology utilizes the cut tree generated during bisection, referred to as a Stored Hierarchical Abstract Relative Placement (SHARP). This cut tree is more typically discarded by other methods. This is referred to as Hierarchical Hybrid Legalization.

For subtrees that contain only standard cells, the cells can be legalized into rows using a variety of methods. A dynamic programming approach derived from {4} may be employed. Critically, the legalization is not to final locations, but to rectangular regions that match the size of the bisection based region. The aspect ratio of the subregion is adjusted to increase and decrease the number of rows (and to increase and decrease width accordingly). Abstract cell positions can be scaled to follow the aspect ratio changes. This results in a set of potential placements for a subtree with only standard cells, with each element of the set having different heights and widths. The subtrees of cells and macro blocks are merged using the cut tree for arrangement. When this merge happens, a set of potential placements is generated. For example, if a left subtree has potential dimensions of (a, b) and (c, d), while the right subtree has (e, f) and (g, h), and the two subtrees are arranged horizontally, four potential arrangements can be produced: (a+e, max(b, f)), (a+g, max(b, h)), (c+e, max(d, f)), (c+g, max(d, h)). Pareto optimization can be used to prune the sets, so that exponential growth is avoided.

See, Özdemir, Sarp, Mohammad Khasawnch, Smriti Rao, and Patrick H. Madden. “Kernel Mapping Techniques for Deep Learning Neural Network Accelerators.” In Proceedings of the 2022 International Symposium on Physical Design (ISPD2022), pp. 21-28. 2022.

The optimization may be performed using a Deep Neural Network. The optimization may be performed by a neural network trained using reinforcement learning. Sec, en.wikipedia.org/wiki/Reinforcement_learning {114-133}.

Deep learning applications are compute intensive and naturally parallel; this has spurred the development of new processor architectures tuned for the work load. In this paper, we consider structural differences between deep learning neural networks and more conventional circuits, highlighting how this impacts strategies for mapping neural network compute kernels onto available hardware. The technology includes an efficient mapping approach based on dynamic programming, and also a method to establish performance bounds.

Deep learning applications typically involve tens to hundreds of layers of computational kernels, implementing functions such as convolution, thresholding, or aggregation of values. The inputs and outputs of each kernel are multidimensional tensors.

With the Cerebras CS-1, kernel operations are compiled and assigned to rectangular grids of compute cores. By unrolling the natural parallelism of a compute kernel, the time required to complete a task can be reduced—but the number of compute cores employed increases.

In the training of a deep learning system, vast numbers of tensors are passed through the kernel graph. Maximizing performance for the CS-1, in which tensors are processed in pipeline fashion, involves minimizing the maximum delay (referred to as δT) of any compute kernel. Throughput of the entire system is more critical than the latency of processing for any single tensor.

Each kernel has formal parameters H, W, for the height and width of the input tensor, R and S to model the complexity of neural network receptors, and C and K to model the depth of the input and outputs. A parameter T is used to model striding operations across the tensors. For deploying a deep learning solution, each kernel also has execution parameters h′, w′, c′ and k′, which express the unrolling of computations that can be performed in parallel.

In many deep learning kernel graphs, there are common groups of convolutions that repeat; these are the “cblock” and “dblock” structures. Each processor core within the CS-1 system has a fixed amount of local memory. As long as memory demands for a kernel fall under this limit, the relevant figures of merit are the height, width, and delay. Any specific implementation of a kernel IDs referred to as a variant, and there are typically a large number of possible variants.

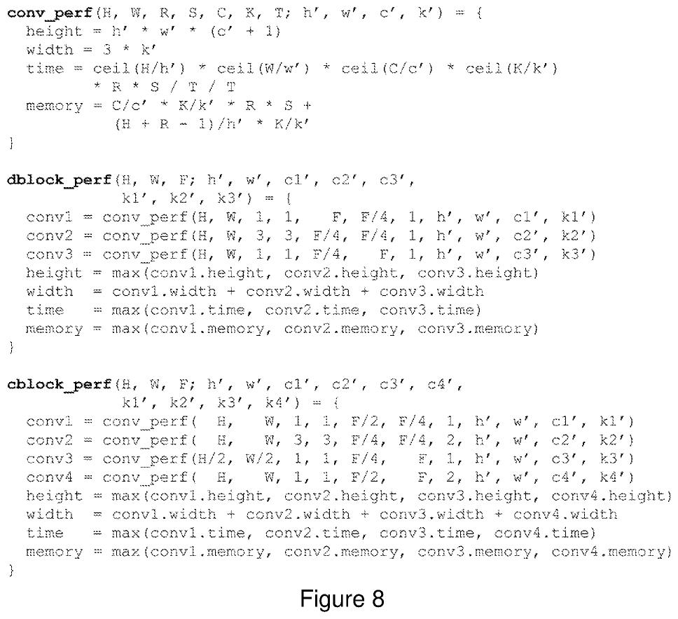

Tuples of [h, w, t] are used to denote the height, width, and time delay of any particular variant, or group of variants; we refer to this as a performance cube. Any variant that exceeds memory constraints, and do not include this value in the performance cubes, is eliminated from consideration. FIG. 8 shows pseudocode for modelling the performance of variants.

Landman and Russo formalized Rent's Rule with the equation P=KBr. In a hierarchical design, B represents the number of blocks within a module, K is the average number of pins per block, and the “Rent parameter” r captures the complexity of the system. P is the number of external pins or connecting terminals of the module. If one has a regular mesh, with nearest-neighbor connections in a grid pattern, r might be 0.5. The number of connections leaving a square subsection of mesh, with n blocks within the module, would be proportional to the square root of the area of the module. An entirely random arrangement of blocks might result in a r value of 1. Rent parameters that are higher than 0.5 imply wiring demand that grows faster than the scaling of a two-dimensional mesh, and can lead to increasing wire lengths (relative to block size) as systems become larger and more complex. Lower observed Rent parameters may also suggest a “better” decomposition of a system into modules.

Landman and Russo observed values of r ranging from 0.57 to 0.75 (and also noted situations in which the rule does not apply). In both partitioning and circuit placement work, across a wide range of circuit applications, many authors have observed the same sorts of interactions between design sizes and interconnect. For analytic and bisection based circuit placement tools, the circuit net list can be viewed as “pulling together,” and spreading the circuit elements apart while minimizing interconnect length is a great challenge.

The deep learning architectures mentioned earlier are nearly linear arrangements of convolution operators, with only a small amount of local branching and reconvergence. Using the equation codified by Landman and Russo, the Rent parameter r is zero; a single tensor flows into and out of each compute kernel, and this does not change even if one were to group a series of kernels together into a cluster. When the Rent parameter r is 0.5 or below, it invites a topological approach to placement.

In one early work on placement suboptimality, Chang presented Placement Examples with Known Optimal (PEKO) benchmarks. These synthetic benchmarks consisted of a grid of square cells, with a mesh-like set of connecting nets. While cardinality of nets varied to match the profile of typical circuit designs, the underlying grid arrangement could be inferred.

Ono utilized the structure of the PEKO benchmarks in a novel way. Net cardinality was used as a proxy for net length, and then Dijkstra's algorithm was applied to find sets of cells that were distant from one another. These distant cells were then used as “corners” of a placement, with other cell locations being found by interpolation based on graph distances to the corners. In fractions of a second, Ono's Beacon placement approach found global placements for the PEKO benchmarks that were far superior to solutions found by traditional placement tools.

In a mapping task, the maximum delay of any kernel, δT, is of concern. The slowest kernel of the graph places an upper bound on throughput, as tensors are processed in a pipeline fashion. The total L1 distance of kernel connections, measured from the centers of each kernel, was also a consideration. While relatively less important, minimizing this is worthwhile. Third, differences in how the parallelism is unrolled in connected blocks can require the introduction of an adapter.

The low Rent parameter of deep learning graphs invites a topological approach, rather than methods based on annealing or bisection.

If a benchmark can be implemented in a single row, the Jiang et al. CU.POKer approach finishes relatively quickly. If more rows are required, however, run times can increase dramatically, as the number of combinations explodes. If there are two rows, one must consider combinations where the first row is h1 cores tall, and the second is 633 h1 cores tall; a substantial increase in the solution space. For three rows, combinations of heights h1, h2, and 633 (h1+h2) must be explored.

The present approach employs an initial topological ordering similar to CU.POKer, but applies dynamic programming to perform kernel selection and mapping. This allows support for more complex performance models, and to implement mappings with multiple rows while avoiding a computational explosion. Key steps are as follows.

The kernel graph is traversed from inputs to outputs, in breadth-first order. The order in which kernels are encountered by this traversal is selected as the order in which to place kernels across the processor.

Potential kernel implementations are generated, through brute-force exploration of different ways in which parallelism can be unrolled. A non-dominated subset of these potential implementations are determined using Bentley's divide and conquer algorithm.

Non-dominated horizontal sequential subsets of kernels are determined with a dynamic programming algorithm; these are optimal “strips” of kernels, from any kernel kᵢ to kⱼ. The strips are stacked into horizontal rows, again using dynamic programming.

By reversing the order of kernels on alternate strips, a serpentine pattern is created, with low interconnection lengths.

While CU.POKer uses numerical methods to find optimal kernel variations for specific height targets, the embodiment uses a simple brute-force approach with an efficient implementation of Bentley's divide and conquer Pareto dominance algorithm to perform filtering.

To be explicit, consider two variants a and b, with performance cubes of [hₐ, wₐ, tₐ] and [h_{b}, w_{b}, t_{b}]. Variant a dominates variant b if hₐ≤h_{b}, wₐ≤w_{b}, and tₐ≤t_{b}. In any situation where a larger, slower variant would be acceptable, replacing it with the smaller, faster option is superior. The brute force approach delivers hundreds of thousands of kernel variant candidates; using the algorithm by Bentley, this can be reduced to a few thousand quickly.

After finding all non-dominated kernel variants, it is possible to establish a firm lower bound on δt for an entire benchmark. For each potential delay, one can find the minimum area (number of cores) necessary for each kernel to meet or exceed that delay, and from this, the minimum area (or number of cores) required in any mapping can be determined.

Similarly to CU.POKer, a binary search is used to consider different potential operating speeds—but start with the established lower bound, and considering potential speeds that are slightly lower, but with less strict area constraints.

For mappings that require multiple rows, CU.POKer has the potential of a computational explosion. The present technology avoids this issue through the use of dynamic programming. For simplicity of description, we will assume that the compute kernels are numbered k₁, k₂, . . . , kₙ, with the ordering as described earlier.

Optimal Single Row Strips. Optimal configurations for horizontal subsequences of kernels (e.g., kernel kᵢ to kⱼ, inclusive) are found. These are referred to as “strips”.

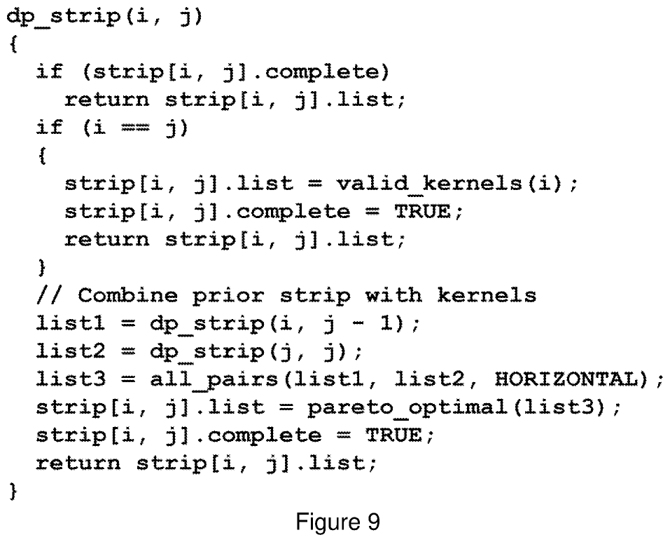

FIG. 9 shows pseudocode for finding non-dominated packings of kernel variants as horizontal strips. Entry (i, j) holds a list of packings, for kernel kᵢ up to and including kⱼ.

The basis case for this approach, an optimal “strip” with a single compute kernel, is simply the set of non-dominated variants. Using dynamic programming, longer sequences may be assembled as follows.

A strip containing kᵢ to kᵢ₊₁ can be formed by finding all combinations from kᵢ and kᵢ₊₁ arranged horizontally, one after another. The height of a combination is the maximum of the heights of the two incoming kernels, while the width is the sum of each width. Bentley's algorithm comes in to play again, quickly finding nondominated combinations.

Finding longer chains of kernel variants, from kᵢ to kⱼ, can be done by combining the variants of kᵢ to the shorter chain kᵢ₊₁ to kⱼ.

A conventional dynamic programming table may be employed, to store optimal solutions for kernel kᵢ to kernel kⱼ; each entry in the table is the set of all non-dominated solutions.

Optimal Stacking of Strips. After constructing strips of compute kernels, strips are arranged into vertical stacks. A dynamic programming approach is again employed. The key insight is to view a series of kernels kᵢ to kⱼ as either a single horizontal run, or a set of stacked horizontal runs from kᵢ to kₖ for some value k, and then from kₖ₊₁ to kⱼ.

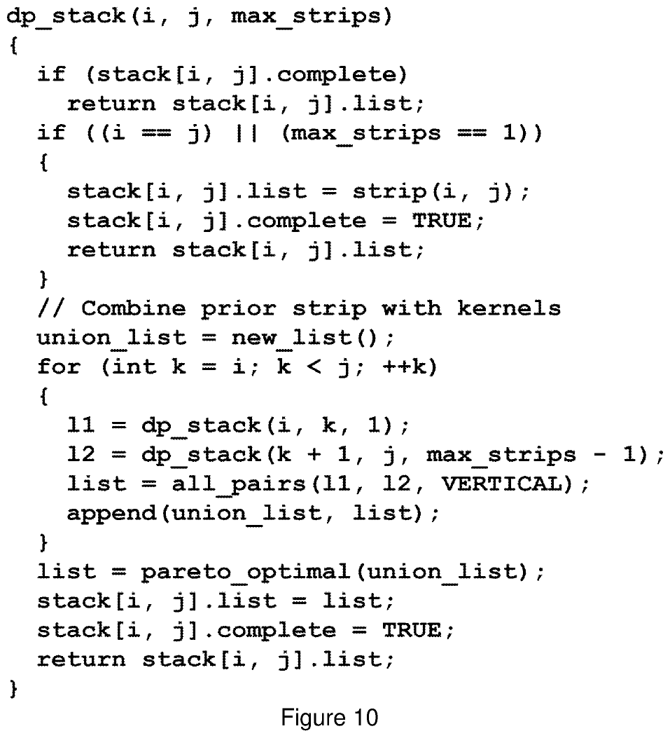

FIG. 10 shows pseudocode for a dynamic programming algorithm to assemble strips of consecutive kernel variants into vertical stacks.

The key difference is iterating through various potential “split points,” breaking the kernels into two or more parts. The stacking algorithm is very similar in structure to matrix chain multiplication. The implementation of the embodiment includes the possibility of limiting the number of strips to stack. This impacts the wire length metric. After “stacking” strips, the arrangement can be modified to a serpentine, snake-like pattern, by reversing the order on alternate strips. As most neural network graphs are linear, or near-linear, this typically provides short connections for such a use case.

Both dynamic programming algorithms are pseudopolynomial in nature. To avoid a computational explosion, there are a variety of simple constraints that can be added, pruning the solution space without degrading solution quality.

First, when searching for a solution, a target speed δt is selected to optimize for. Any kernel variant that exceeds δt can be discarded. In general, the threshold target speed may be updated adaptively as possible solutions are analyzed. At the same time, kernels that consume too much area can also be ignored. The performance leveling described earlier can identify the minimum area required to achieve a speed St, which also reveals the amount of unassigned area available before exceeding the total space available. These two constraints effectively form upper and lower bounds on the sizes of any kernel that must be considered. In the even that a post process modifies the layout, a set of near-optimal solutions may be maintained, in case a putative best solution fails for some reason.

When two kernels (or sets of kernels) are combined, there can be “wasted space.” For example, if we combine kernels horizontally, and one is taller than the other, the area above the “shorter” kernel is lost. As solutions are constructed with dynamic programming, the amount of “wasted space” may be tracked within each intermediate solution. If the waste exceeds the slack available, no solution will be possible, and the solution can again be pruned.

These few optimizations enable solutions to be found quickly and easily for all benchmark problems.

Experimental Results with ISPD Benchmarks

To evaluate the approach, a series of experiments were performed on the benchmark neural network kernel graphs that are part of the ISPD2020 contest suite. Experimental results of the benchmarks are shown in Table 8, which shows results from the present approach, and also those of CU.POKer, the winner of the ISPD contest; because the benchmark metrics do not consider wiring internal to each block, there is no penalty for high aspect-ratio implementations.

Eight benchmarks were publicly released for testing and debugging, and another twelve were kept secret by the contest organizers. There are ten different kernel graphs, each graph being evaluate twice, once with a metric that weighted δT and connection lengths equally, and once where the connection lengths are more heavily weighted. Each benchmark is named with a single letter. “A” is a benchmark with a 1:1 metric, while “E” is the same graph with a 1:10 metric.

The size of the kernel graphs, and the number of connections, are shown as k and c. For each benchmark, the minimum δT value that is theoretically possible may be determined, by considering the different feasible speeds for each kernel, and the minimum area required for each kernel to attain that speed, and then comparing the area demands to the number of compute cores available on the CS-1.

Across the designs, the present approach produces the smallest δT value for all but two cases.

Across all of the benchmarks, the present approach is within a few percent of the theoretical optimum δT, and achieves almost complete utilization of the hundreds of thousands of compute cores on the CS-1. Benchmarks K, L, Q, and R have lower utilization. In these cases, all available parallelism has been “unrolled,” and there is an overabundance of compute resources.

To evaluate the impact of chaining accelerators together, experiments were performed with dividing kernel graphs across four processors; results are shown in Table 9. The kernel ordering was used from a topological search, a simple greedy algorithm used to assign kernels, and then the present placement approach was used on the portion of the graph assigned to each processor. Wire length was ignored, resulting in only some of the benchmarks being considered. The benchmarks K, L, Q, and R can be unrolled completely on a single CS-1, and are not considered.

Speedup on four processors ranges from 3.21× to 3.94×, and is 3.61× on average. There are limits to how far this can go (splitting a kernel across two processors would not be practical), but these results are promising. Even with massive system such as the CS-1, there is “more parallelism available.”

If one were to partition a large conventional circuit into two subcomponents, the number of connections spanning the two components is typically large, and there would also typically be bidirectional data flow.

While the kernel mapping problem resembles classic floor planning in some respects, there are key differences; the near-linear structure of most kernel graphs makes a topology-driven approach most effective.

An efficient method is presented to find all non-dominated kernel variants, dynamic programming methods to size and place the variants, as well as experiments that suggest further acceleration is possible with multiple CS-1 systems.

Performance bounds were established for kernel graphs, and the resulting approach is within a few percent of that bound. In most benchmarks, almost all available processing cores can be utilized.

Placement legalization approaches typically try to minimize the displacement between abstract and legal positions. The present technology minimizes the change in location between pairs of cells, the ability to shift logic elements en masse avoids a wire length explosion, and simplifies finding an overlap-free arrangement. The Pareto optimization during packing can also consider wire lengths. The entire approach can be seen as a form of dynamic programming.

Beyond the legalization, the use of the cut tree offers a number of other benefits:
(a) Routing congestion can be addressed through precision white space insertion. Space can be allocated around congested routing elements, and then the areas of each bisection-based region can be updated to account for that added space. The legalization process can then be applied, with logic elements shifting slightly, but maintaining their relative positions. This idea is a generalization of an earlier publication on white space allocation {64}.
(b) Performance optimization can be done incrementally. Typically, an input circuit netlist features only logic elements needed for correct function. To maximize performance, buffers are inserted into timing critical nets (making signal transmission faster, but not changing function). The locations of buffers are critical: they are usually equally spaced on a long net connect. Typically, circuits are required to reserve a certain percentage of white space to accommodate the buffer insertion without disrupting the overall placement. With the bisection cut tree, a leaf vertex can be split in two between a circuit element and a buffer, allowing precision placement of buffers. Legalization is applied to the modified tree, and the buffer is then located in an appropriate location.
(c) The use of cut trees allows for individual logic blocks to be placed and optimized independently. The trees for each logic block can be grafted onto the cut tree of an overall design, and then the entire design can be legalized.
(e) If the overall design replicates a component multiple times, the cut tree for the component can be grafted multiple times. Handling rotations and mirroring is a trivial extension.
(f) IP netlists generated by automated systems can also provide cut trees of “known good” placements, allowing for fast prototyping. These cut trees may be treated as macro blocks in subsequent designs and layouts.

The disclosure has been described with reference to various specific embodiments and techniques. However, many variations and modifications are possible while remaining within the scope of the disclosure.

### Incorporation by Reference and Interpretation of Language

Citation or identification of any reference herein, in any section of this application, shall not be construed as an admission that such reference is necessarily available as prior art to the present application.

The disclosures of each reference disclosed herein, whether U.S. or foreign patent literature, or non-patent literature, are hereby incorporated by reference in their entirety in this application, and shall be treated as if the entirety thereof forms a part of this application.

All cited or identified references are provided for their disclosure of technologies to enable practice of the present invention, to provide basis for claim language, and to make clear applicant's possession of the invention with respect to the various aggregates, combinations, and subcombinations of the respective disclosures or portions thereof (within a particular reference or across multiple references). The citation of references is intended to be part of the disclosure of the invention, and not merely supplementary background information. The incorporation by reference does not extend to teachings which are inconsistent with the invention as expressly described herein (which may be treated as counter examples), and is evidence of a proper interpretation by persons of ordinary skill in the art of the terms, phrase and concepts discussed herein, without being limiting as the sole interpretation available.

The present specification is not properly interpreted by recourse to lay dictionaries in preference to field-specific dictionaries or usage. Where a conflict of interpretation exists, the hierarchy of resolution shall be the intrinsic evidence of the express specification, references cited for propositions, incorporated references, followed by the extrinsic evidence of the inventors' prior publications relating to the field, academic literature in the field, commercial literature in the field, field-specific dictionaries, lay literature in the field, general purpose dictionaries, and common lay understanding.

The Appendices to the specification are incorporated herein by reference.

### REFERENCES

1. S. N. Adya and I. L. Markov. Fixed-outline floorplanning through better local search. In Proc. IEEE Int. Conf. on Computer Design, pages 328-334, 2001.
2. S. N. Adya and I. L. Markov. Consistent placement of macroblock using floorplanning and standard-cell placement. In Proc. Int. Symp. on Physical Design, pages 12-17, 2002.
3. S. N. Adya, I. L. Markov, and P. G. Villarrubia. On whitespace in mixed-size placement and physical synthesis. In Proc. Int. Conf. on Computer Aided Design, pages 311-318, 2003.
4. A. Agnihotri, M. C. Yildiz, A. Khatkhate, A. Mathur, S. Ono, and P. H. Madden. Fractional cut: Improved recursive bisection placement. In Proc. Int. Conf. on Computer Aided Design, pages 307-310, 2003.
5. C. J. Alpert. The ispd98 circuit benchmark suite. In Proc. Int. Symp. on Physical Design, pages 80-85, 1998.
6. M. A. Breuer. A class of min-cut placement algorithms. In Proc. Design Automation Conf, pages 284-290, 1977.
7. Andrew E. Caldwell, Andrew B. Kahng, and Igor L. Markov. Can recursive bisection alone produce routable placements? In Proc. Design Automation Conf, pages 477-482, 2000.
8. C. C. Chang, J. Cong, and X. Yuan. Multi-level placement for large-scale mixed-size ic designs. In Proc. Asia South Pacific Design Automation Conf., pages 325-330, 2003.
9. Jason Cong, Lei He, Cheng-Kok Koh, and Patrick H. Madden. Performance optimization of VLSI interconnectlayout. Integration, the VLSI Journal, 21:1-94, 1996.
10. A. E. Dunlop and B. W. Kernighan. A procedure for placement of standard-cell VLSI circuits. IEEE Trans. on Computer-Aided Design of Integrated Circuits and Systems, CAD-4 (1): 92-98, January 1985.
11. H. Eisenmann and F. M. Johannes. Generic global placement and floorplanning. In Proc. Design Automation Conf, pages 269-274, 1998.
12. GSRC. Bookshelf slot. www.gigascale.org/bookshelf.
13. D. Hill. U.S. Pat. No. 6,370,673: Method and system for high speed detailed placement of cells within an integrated circuit design, 2002.
14. G. Karypis, R. Aggarwal, V. Kumar, and S. Shekhar. Multilevel hypergraph partitioning: Application in VLSI domain. In Proc. Design Automation Conf, pages 526-529, 1997.
15. J. Kleinhans, G. Sigl, F. Johannes, and K. Antreich. GORDIAN: VLSI placement by quadratic programming and slicing optimization. IEEE Trans. on Computer-Aided Design of Integrated Circuits and Systems, 10 (3): 356-365, 1991.
16. C. Li and C.-K. Koh. On improving recursive bipartitioning-based placement. Technical Report TR-ECE-03-14, Purdue University ECE, 2003.
17. J.-M. Lin and Y.-W. Chang. TCG: A transitive closure graph based representation for non-slicing floorplans. In Proc. Design Automation Conf, 2001.
18. H. Murata, K. Fujiyoshi, S. Nakatake, and Y. Kajitani. VLSI module placement based on rectangle-packing by the sequence pair. IEEE Trans. on Computer-Aided Design of Integrated Circuits and Systems, 15 (12): 1518-1524, 1996.
19. R. H. J. M. Otten. What is a floorplan? In Proc. Int. Symp. on Physical Design, pages 201-206, 2000.
20. Yingxin Pang, Florin Balasa, Koen Lampaert, and Chung-Kuan Cheng. Block placement with symmetry constraints based on the o-tree non-slicing representation. In Proc. Design Automation Conf, pages 464-467, 2000.
21. C. Sechen. Chip-planning, placement, and global routing of macro/custom cell integrated circuits using simulated annealing. In Proc. Design Automation Conf, pages 73-80, 1988.
22. A. Shanbhag, S. Danda, and N. Sherwani. Floorplanning for mixed macro block and standard cell designs. In Proc. Great Lakes Symposium on VLSI, pages 26-29, 1994.
23. W. Swartz and C. Sechen. Timing driven placement for large standard cell circuits. In Proc. Design Automation Conf, pages 211-215, 1995.
24. W. P. Swartz. Automatic layout of analog and digital mixed macro/standard cell integrated circuits. Yale Thesis, Chapter 4, 1993.
25. M. Upton, K. Samii, and S. Sugiyama. Integrated placement for mixed macro cell and standard cell designs. In Proc. Design Automation Conf, pages 32-35, 1990.
26. Maogang Wang, Xiaojian Yang, and Majid Sarrafzadeh. Dragon2000: Standard-cell placement tool for large industry circuits. In Proc. Int. Conf. on Computer Aided Design, pages 260-263, 2000.
27. H. Yu, X. Hong, and Y. Cai. Mmp: a novel placement algorithm for combined macro block and standard cell layout design. In Proc. Asia South Pacific Design Automation Conf., pages 271-276, 2000.
28. Khatkhate, Ateen, Chen Li, Ameya R. Agnihotri, Mehmet C. Yildiz, Satoshi Ono, Cheng-Kok Koh, and Patrick H. Madden. “Recursive bisection based mixed block placement.” In Proceedings of the 2004 international symposium on Physical design, pp. 84-89. 2004
29. Agnihotri, Ameya, Mehmet Can Yildiz, Ateen Khatkhate, Ajita Mathur, Satoshi Ono, and Patrick H. Madden. “Fractional cut: Improved recursive bisection placement.” In ICCAD-2003. International Conference on Computer Aided Design (IEEE Cat. No. 03CH37486), pp. 307-310. IEEE, 2003
30. Mirhoseini, Azalia, Anna Goldie, Mustafa Yazgan, Joe Wenjie Jiang, Ebrahim Songhori, Shen Wang, Young-Joon Lee et al. “A graph placement methodology for fast chip design.” Nature 594, no. 7862 (2021): 207-212.
31. Cheng, Chung-Kuan, Andrew B. Kahng, Sayak Kundu, Yucheng Wang, and Zhiang Wang. “Assessment of Reinforcement Learning for Macro Placement.” arXiv preprint arXiv: 2302.11014 (2023); In Proceedings of the 2023 International Symposium on Physical Design (ISPD '23), Mar. 26-29, 2023, Virtual Event, USA. ACM, New York, NY, USA, 12 pages. doi.org/10.1145/3569052.3578926.
32. “Stronger Baselines for Evaluating Deep Reinforcement Learning in Chip Placement”, August 2022. statmodeling.stat.columbia.edu/wp-content/uploads/2022/05/MLcontra.pdf.
33. S. Kirkpatrick, C. D. Gelatt, and M. P. Vecchi. Optimization by simulated annealing. Science, 220 (4598): 671-680, May 1983.
34. B. W. Kernighan and S. Lin. An efficient heuristic procedure for partitioning graphs. Bell System Technical Journal, 49:291-307, 1970.
35. C. M. Fiduccia and R. M. Mattheyses. A linear-time heuristic for improving network partitions. In Proceedings of the 19th IEEE Design Automation Conference, pages 175-181, 1982.
36. A. Mirhoseini, A. Goldie, M. Yazgan, J. W. Jiang, E. Songhori, S. Wang, Y.-J. Lee, E. Johnson, O. Pathak, A. Nazi, J. Pak, A. Tong, K. Srinivasa, W. Hang, and E. Tuncer. A graph placement methodology for fast chip design. Nature, 594 (June 2021): 207-212, 2021.
37. M. R. Garey and D. S. Johnson. Computers and Intractability: A Guide to the Theory of NP-Completeness. W.H. Freeman and Co., San Francisco, CA, 1979. page 209.
38. R. H. J. M. Otten. What is a floorplan? In Proc. Int. Symp. on Physical Design, pages 201-206, 2000.
39. H. Murata, K. Fujiyoshi, S. Nakatake, and Y. Kajitani. VLSI module placement based on rectangle-packing by the sequence pair. IEEE Trans. on Computer-Aided Design of Integrated Circuits and Systems, 15 (12): 1518-1524, 1996.
40. A. R. Agnihotri, M. C. Yildiz, A. Khatkhate, A. Mathur, S. Ono, and P. H. Madden. Fractional Cut: Improved recursive bisection placement. In Proc. Int. Conf. on Computer Aided Design, pages 307-310, 2003.
41. Andrew B. Kahng and Qinke Wang. An analytic placer for mixed-size placement and timing-driven placement, 2004.
42. G. Karypis, R. Aggarwal, V. Kumar, and S. Shekhar. Multilevel hypergraph partitioning: Application in VLSI domain. In Proc. Design Automation Conf, pages 526-529, 1997.
43. D. S. Johnson, C. R. Aragon, L. A. McGeoch, and C. Schevon. Optimization by simulated annealing; part I, graph partitioning. Operations Research, 37:865-892, 1989.
44. J. Cong and M. Smith. A parallel bottom-up clustering algorithm with applications to circuit partitioning in VLSI design. In Proc. Design Automation Conf, pages 755-780, 1993.
45. C. J. Alpert. The ISPD98 circuit benchmark suite. In Proc. Int. Symp. on Physical Design, pages 80-85, 1998.
46. S. N. Adya and I. L. Markov. Consistent placement of macroblock using floorplanning and standard-cell placement. In Proc. Int. Symp. on Physical Design, pages 12-17, 2002.
47. A. Khatkhate, C. Li, A. R. Agnihotri, M. C. Yildiz, S. Ono, C.-K. Koh, and P. H. Madden. Recursive bisection based mixed block placement. In Proc. Int. Symp. on Physical Design, pages 84-89, 2004.
48. D. Hill. U.S. Pat. No. 6,370,673: Method and system for high speed detailed placement of cells within an integrated circuit design, 2002.
49. S. N. Adya, I. L. Markov, and P. G. Villarrubia. On whitespace in mixed-size placement and physical synthesis. In Proc. Int. Conf. on Computer Aided Design, pages 311-318, 2003.
50. C. C. Chang, J. Cong, and X. Yuan. Multi-level placement for large-scale mixedsize ic designs. In Proc. Asia South Pacific Design Automation Conf., pages 325-330, 2003.
51. B. Yao, H. Chen, C.-K. Cheng, N.-C. Chou, L.-T. Liu, and P. Suaris. Unified Quadratic Programming Approach for Mixed Mode Placement. Proc. ISPD, pages 193-199, 2005.
52. Aaron Ng, Igor L. Markov, Rajat Aggarwal, and Venky Ramachandran. Solving hard instances of floorplacement. Proceedings of the International Symposium on Physical Design, 2006:170-177, 2006.
53. G.-J. Nam, C. J. Alpert, P. Villarrubia, B. Winter, and M. Yildiz. The ISPD2005 placement contest and benchmark suite. In Proc. Int. Symp. on Physical Design, pages 216-220, 2005.
54. Jackey Z. Yan, Natarajan Viswanathan, and Chris Chu. An Effective floorplanGuided placement algorithm for large-Scale mixed-Size designs. ACM Transactions on Design Automation of Electronic Systems, 19 (3), 2014.
55. Szu-to Chen, Yao-wen Chang, Tung-chich Chen, and Maxeda Technology. An Integrated-Spreading-Based Macro-Refining Algorithm for Large-Scale MixedSize Circuit Designs. IEEE Trans. on Computer-Aided Design of Integrated Circuits and Systems, pages 496-503, 2017.
56. M. Khasawnch and P. H. Madden. Hill climbing with trees: Detail placement for large windows. In Proc. Int. Symp. on Physical Design, pages 1-8, 2020.
57. M. Khasawneh and P. H. Madden. HydraRoute: A novel approach to circuit routing. In Proc. Great Lakes Symposium on VLSI, pages 177-182, 2019.
58. C. J. Alpert, G.-J. Nam, P. G. Villarrubia, and M. C. Yildiz. Placement stability metrics. In Proc. Asia South Pacific Design Automation Conf., pages 1144-1147, 2005.
59. Zixuan Jiang, Ebrahim Songhori, Shen Wang, Anna Goldie, Azalia Mirhoseini, Joe Jiang, Young Joon Lee, and David Z. Pan. Delving into Macro Placement with Reinforcement Learning. 2021 ACM/IEEE 3rd Workshop on Machine Learning for CAD, MLCAD 2021, pages 2-4, 2021.
60. Nima Karimpour Darav, Ismail S. Bustany, Andrew Kennings, and Ravi Mamidi. ICCAD-2017 CAD contest in multi-deck standard cell legalization and benchmarks. IEEE/ACM International Conference on Computer-Aided Design, Digest of Technical Papers, ICCAD, 2017-November: 867-871, 2017.
61. Jackey Z. Yan, Natarajan Viswanathan, and Chris Chu. Handling complexities in modern large-scale mixed-size placement. Proceedings Design Automation Conference, pages 436-441, 2009.
62. Ismail S. Bustany, Jinwook Jung, Patrick H. Madden, Natarajan Viswanathan, and Stephen Yang. Still benchmarking after all these years. Proceedings of the International Symposium on Physical Design, pages 47-52, 2021.
63. Li, Chen, Min Xie, Cheng-Kok Koh, Jason Cong, and Patrick H. Madden. “Routability-driven placement and white space allocation.” IEEE Transactions on Computer-aided design of Integrated Circuits and Systems 26, no. 5 (2007): 858-871.
64. Sarrafzadeh, Majid, Maogang Wang, and Xiaojian Yang. Modern placement techniques. Springer Science & Business Media, 2003.
65. Stenz, Guenter, Bernhard M. Riess, Bernhard Rohfleisch, and Frank M. Johannes. “Timing driven placement in interaction with netlist transformations.” In Proceedings of the 1997 international symposium on Physical design, pp. 36-41. 1997.
66. Taghavi, Taraneh, Xiaojian Yang, and Bo-Kyung Choi. “Dragon2005: Large-scale mixed-size placement tool.” In Proceedings of the 2005 international symposium on Physical design, pp. 245-247. 2005.
67. Tang, Xiaoping, Ruiqi Tian, and Martin D F Wong. “Optimal redistribution of white space for wire length minimization.” In Proceedings of the 2005 Asia and South Pacific Design Automation Conference, pp. 412-417. 2005.
68. M. A. Breuer, “Min-cut placement,” J. Design Fault-Tolerant Comput., vol. 1, no. 4, pp. 343-362, 1977.
69. B. W. Kernighan and L. Lin, “An efficient heuristic procedure for partitioning graphs,” Bell Syst. Tech. J., vol. 49, pp. 291-307, 1970.
70. C. M. Fiduccia and R. M. Mattheyses, “A linear-time heuristic for improving network partitions,” in Proc. 19th Design Automation Workshop, pp. 175-181, 1982.
71. H. Shiraishi and F. Hirosi, “Efficient placement and routing for masterslice LSI,” in Proc. 17th Design Automation Conference, Minneapolis, MN, pp. 458-464, 1980.
72. A. Vannelli and G. S. Rowan, “A constrained clustering approach for partitioning netlists,” in Proc. 28th Midwest Symp. on Circuits and Systems, Imisville, KY, pp. 211-215, 1985.
73. R. E. Gomory and T. C. Hu, “Multi-terminal network flows,” J. SUM, vol. 9, no. 4, pp. 551-570, 1961.
74. E. L. Lawler, “Cutsets and partitions of hypergraphs,” Networks, vol. 3, pp. 275-285, 1973.
75. D. G. Schweikert and B. W. Kernighan, “A proper model for the partitioning of electrical circuits,” In Proc. 9th Design Automation Workshop, Dallas, TX, pp. 57-62, 1972.
76. T. C. Hu, Integer Programming and Network Flows. Reading, MA: Addison-Wesley, 1970.
77. M. W. Padberg and M. R. Rao, “Odd minimum cut-sets and b-matchings,” Math. Oper. Res., vol. 7, no. 1, pp. 67-80, 1982.
78. G. E. Moore. Cramming more components onto integrated circuits. Electronics Magazine, 38 (8): 114-117, April 1965.
79. K. He, X. Zhang, S. Ren, and J. Sun. Deep residual learning for image recognition.arxiv.org/pdf/1512.03385.pdf, 2015.
80. D. Silver, T. Hubert, J. Schrittwieser, I. Antonoglou, M. Lai, A. Guez, M. Lanctot, L. Sifre, D. Kumaran, T. Graepel, T. Lillicrap, K. Simonyan, and D. Hassabis. Mastering chess and shogi by self-play with a general reinforcement learning algorithm. arxiv.org/pdf/1712.01815.pdf, 2017.
81. J. P. Fricker and A. Hock. CS-1 wafer-scale deep learning system. In Proc. Supercomputing, 2019. tinyurl.com/txuzcps.
82. L. Song, J. Mao, Y. Zhuo, X. Qian, H. Li, and Y. Chen. HyPar: towards hybrid parallelism for deep learning accelerator array. In Proc. HPCA, pages 56-68, 2019.
83. Y. Chen, Y. Xie, L. Song, F. Chen, and T. Tang. A survey of accelerator architectures for deep neural networks. Engineering, (6): 254-274, 2020.
84. M. James, M. Tom, P. Groeneveld, and V. Kibardin. ISPD 2020 physical mapping of neural networks on a wafer-scale deep learning accelerator. In Proc. International Symposium on Physical Design, pages 1-5, 2020.
85. Jon Louis Bentley. Multidimensional divide-and-conquer. Commun. ACM, 23 (4): 214-229, April 1980.
86. B. Jiang, J. Chen, J. Liu, L. Liu, F. Wang, X. Zhang, and E. F.-Y. Young. CU.POKer: Placing DNNs on wafer-scale AI accelerator with optimal kernel sizing. In Proc. ICCAD, 2020.
87. K. Simonyan and A. Zisserman. Very deep convolutional networks for large-scale image recognition. In ICLR, 2015.
88. M. C. Yildiz and P. H. Madden. Improved cut sequences for partitioning based placement. In Proc. Design Automation Conf, pages 776-779, 2001.
89. B. Landman and R. Russo. On a pin versus block relationship for partitioning of logic graphs. IEEE Trans. on Computers, C-20:1469-1479 December. 1971.
90. J. Dambre, P. Verplaetse, D. Stroobandt, and J. Van Campenhout. On Rent's rule for rectangular regions. In Proc. System Level Interconnect Prediction Workshop, pages 49-56, 2001.
91. L. K. Scheffer. The physical design of biological systems-insights from the brain. In Proc. ISPD, pages 101-108, 2021.
92. C. C. Chang, J. Cong, and M. Xie. Optimality and scalability study of existing placement algorithms. In Proc. Asia South Pacific Design Automation Conf., pages 621-627, 2003.
93. S. Ono and P. H. Madden. On structure and suboptimality in placement. In Proc. Asia South Pacific Design Automation Conf., pages 331-336, 2005.
94. T. H. Cormen, C. E. Leiserson, and R. L. Rivest. Introduction to Algorithms. MIT Press, 1990.
95. G. M. Amdahl. Validity of the single-processor approach to achieving large scale computing capabilities. In Proc. AFIPS Conference, pages 483-485, 1967.
96. G. E. Moore. Cramming more components onto integrated circuits. Electronics Magazine, 38 (8): 114-117, April 1965.
97. K. He, X. Zhang, S. Ren, and J. Sun. Deep residual learning for image recognition.arxiv.org/pdf/1512.03385.pdf, 2015.
98. D. Silver, T. Hubert, J. Schrittwieser, I. Antonoglou, M. Lai, A. Guez, M. Lanctot, L. Sifre, D. Kumaran, T. Graepel, T. Lillicrap, K. Simonyan, and D. Hassabis. Mastering chess and shogi by self-play with a general reinforcement learning algorithm. arxiv.org/pdf/1712.01815.pdf, 2017.
99. J. P. Fricker and A. Hock. CS-1 wafer-scale deep learning system. In Proc. Supercomputing, 2019. tinyurl.com/txuzcps.
100. L. Song, J. Mao, Y. Zhuo, X. Qian, H. Li, and Y. Chen. HyPar: towards hybrid parallelism for deep learning accelerator array. In Proc. HPCA, pages 56-68, 2019.
101. Y. Chen, Y. Xie, L. Song, F. Chen, and T. Tang. A survey of accelerator architectures for deep neural networks. Engineering, (6): 254-274, 2020.
102. M. James, M. Tom, P. Groeneveld, and V. Kibardin. ISPD 2020 physical mapping of neural networks on a wafer-scale deep learning accelerator. In Proc. International Symposium on Physical Design, pages 1-5, 2020.
103. Jon Louis Bentley. Multidimensional divide-and-conquer. Commun. ACM, 23 (4): 214-229, April 1980.
104. B. Jiang, J. Chen, J. Liu, L. Liu, F. Wang, X. Zhang, and E. F.-Y. Young. CU.POKer: Placing DNNs on wafer-scale AI accelerator with optimal kernel sizing. In Proc. ICCAD, 2020.
105. K. Simonyan and A. Zisserman. Very deep convolutional networks for large-scale image recognition. In ICLR, 2015.
106. M. C. Yildiz and P. H. Madden. Improved cut sequences for partitioning based placement. In Proc. Design Automation Conf, pages 776-779, 2001.
107. B. Landman and R. Russo. On a pin versus block relationship for partitioning of logic graphs. IEEE Trans. on Computers, C-20:1469-1479 December. 1971.
108. J. Dambre, P. Verplaetse, D. Stroobandt, and J. Van Campenhout. On Rent's rule for rectangular regions. In Proc. System Level Interconnect Prediction Workshop, pages 49-56, 2001.
109. L. K. Scheffer. The physical design of biological systems-insights from the brain. In Proc. ISPD, pages 101-108, 2021.
110. C. C. Chang, J. Cong, and M. Xie. Optimality and scalability study of existing placement algorithms. In Proc. Asia South Pacific Design Automation Conf., pages 621-627, 2003.
111. S. Ono and P. H. Madden. On structure and suboptimality in placement. In Proc. Asia South Pacific Design Automation Conf., pages 331-336, 2005.
112. T. H. Cormen, C. E. Leiserson, and R. L. Rivest. Introduction to Algorithms. MIT Press, 1990.
113. M. Amdahl. Validity of the single-processor approach to achieving large scale computing capabilities. In Proc. AFIPS Conference, pages 483-485, 1967.
114. Liao, Renjie, Marc Brockschmidt, Daniel Tarlow, Alexander L. Gaunt, Raquel Urtasun, and Richard Zemel. “Graph partition neural networks for semi-supervised classification.” arXiv preprint arXiv: 1803.06272 (2018).
115. Xu, Haoyan, Ziheng Duan, Yueyang Wang, Jie Feng, Runjian Chen, Qianru Zhang, and Zhongbin Xu. “Graph partitioning and graph neural network based hierarchical graph matching for graph similarity computation.” Neurocomputing 439 (2021): 348-362.
116. Kawamoto, Tatsuro, Masashi Tsubaki, and Tomoyuki Obuchi. “Mean-field theory of graph neural networks in graph partitioning.” Advances in Neural Information Processing Systems 31 (2018).
117. Den Bout, Van. “Graph partitioning using annealed neural networks.” In International 1989 Joint Conference on Neural Networks, pp. 521-528. IEEE, 1989.
118. Wu, Zhengtian, Hamid Reza Karimi, and Chuangyin Dang. “An approximation algorithm for graph partitioning via deterministic annealing neural network.” Neural networks 117 (2019): 191-200.
119. Pain, C. C., CR E. De Oliveira, and A. J. H. Goddard. “A neural network graph partitioning procedure for grid-based domain decomposition.” International journal for numerical methods in engineering 44, no. 5 (1999): 593-613.
120. Ma, Jiaqi, Ziqiao Ma, Joyce Chai, and Qiaozhu Mei. “Partition-based active learning for graph neural networks.” arXiv preprint arXiv: 2201.09391 (2022).
121. Zhang, Niansong, Xiang Chen, and Nachiket Kapre. “Rapidlayout: Fast hard block placement of fpga-optimized systolic arrays using evolutionary algorithm.” ACM Transactions on Reconfigurable Technology and Systems (TRETS) 15, no. 4 (2022): 1-23.
122. Kim, Sung-Soo, and Chong-Min Kyung. “Circuit placement on arbitrarily shaped regions using the self-organization principle.” IEEE transactions on computer-aided design of integrated circuits and systems 11, no. 7 (1992): 844-854.
123. Zhang, Niansong, Xiang Chen, and Nachiket Kapre. “Rapidlayout: Fast hard block placement of fpga-optimized systolic arrays using evolutionary algorithm.” ACM Transactions on Reconfigurable Technology and Systems (TRETS) 15, no. 4 (2022): 1-23.
124. Groeneveld, Patrick, Michael James, Vladimir Kibardin, Ilya Sharapov, Marvin Tom, and Leo Wang. “ISPD 2021 wafer-scale physics modeling contest: A new frontier for partitioning, placement and routing.” In Proceedings of the 2021 International Symposium on Physical Design, pp. 143-147. 2021.
125. Le, Tuyen P., Hieu T. Nguyen, Seungycol Back, Tacyoun Kim, Jungwoo Lee, Scongjung Kim, Hyunjin Kim et al. “Toward Reinforcement Learning-based Rectilinear Macro Placement Under Human Constraints.” arXiv preprint arXiv: 2311.03383 (2023).
126. Liu, Yiting, Ziyi Ju, Zhengming Li, Mingzhi Dong, Hai Zhou, Jia Wang, Fan Yang, Xuan Zeng, and Li Shang. “Graphplanner: Floorplanning with graph neural network.” ACM Transactions on Design Automation of Electronic Systems 28, no. 2 (2022): 1-24.
127. Gu, Hao, Jian Gu, Keyu Peng, Ziran Zhu, Ning Xu, Xin Geng, and Jun Yang. “LAMPlace: Legalization-Aided Reinforcement Learning Based Macro Placement for Mixed-Size Designs With Preplaced Blocks.” IEEE Transactions on Circuits and Systems II: Express Briefs (2024).
128. Shi, Yunqi, Ke Xue, Song Lei, and Chao Qian. “Macro Placement by Wire-Mask-Guided Black-Box Optimization.” Advances in Neural Information Processing Systems 36 (2024).
129. Yan, Junchi, Xianglong Lyu, Ruoyu Cheng, and Yibo Lin. “Towards machine learning for placement and routing in chip design: a methodological overview.” arXiv preprint arXiv: 2202.13564 (2022).
130. Tan, Zhentao, and Yadong Mu. “Hierarchical reinforcement learning for chip-macro placement in integrated circuit.” Pattern Recognition Letters (2024).
131. Hao, Rui, Yici Cai, and Qiang Zhou. “Intelligent and kernelized placement: A survey.” Integration 86 (2022): 44-50.
132. Khasawneh, Mohammad A. “Hill-Climbing With Trees: A Novel Heuristic Approach for Discrete NP-Hard Combinatorial Optimization Problems.” PhD diss., State University of New York at Binghamton, 2023.
133. Massimino, Davide. “Study and development of design techniques for 3D integrated circuits.” PhD diss., Politecnico di Torino, 2021.
134. Dally, William, James Balfour, David Black-Schaffer, Paul Hartke, and Stanford Univ Ca Computer Systems Lab. Structured Application-Specific Integrated Circuit (ASIC) Study. Tech. Rep. Stanford Univ Ca Computer Systems Lab, 2008.
135. Jiang, Bentian, Jingsong Chen, Jinwei Liu, Lixin Liu, Fangzhou Wang, Xiaopeng Zhang, and Evangeline F Y Young. “CU. POKer: Placing DNNs on WSE With Optimal Kernel Sizing and Efficient Protocol Optimization.” IEEE Transactions on Computer-Aided Design of Integrated Circuits and Systems 41, no. 6 (2021): 1888-1901.
Yoon, Jonghee W., Jongeun Lee, Jaewan Jung, Sanghyun Park, Yongjoo Kim, Yunheung Pack, and Doosan Cho. “I 2 CRF: Incremental interconnect customization for embedded reconfigurable fabrics.” In 2011 Design, Automation & Test in Europe, pp. 1-6. IEEE, 2011.
Yoon, Jonghec W., Jongeun Lee, Sanghyun Park, Yongjoo Kim, Jinyong Lee, Yunheung Pack, and Doosan Cho. “Architecture customization of on-chip reconfigurable accelerators.” ACM Transactions on Design Automation of Electronic Systems (TODAES) 18, no. 4 (2013): 1-22.
U.S. Pat. Nos. 4,495,559; 4,630,219; 4,754,408; 4,890,238; 4,908,772; 4,918,614; 5,140,402; 5,140,526; 5,191,542; 5,222,030; 5,225,991; 5,267,176; 5,308,798; 5,309,370; 5,309,371; 5,311,443; 5,367,469; 5,398,195; 5,418,733; 5,448,493; 5,475,607; 5,485,396; 5,493,508; 5,493,510; 5,495,419; 5,506,788; 5,513,119; 5,526,277; 5,526,517; 5,537,332; 5,541,849; 5,544,066; 5,544,067; 5,544,342; 5,553,002; 5,553,276; 5,555,201; 5,557,531; 5,557,533; 5,566,078; 5,572,436; 5,572,437; 5,578,840; 5,579,237; 5,598,344; 5,623,418; 5,636,125; 5,638,292; 5,640,327; 5,650,938; 5,659,717; 5,661,663; 5,666,289; 5,682,321; 5,682,322; 5,696,693; 5,699,265; 5,731,985; 5,742,086; 5,742,510; 5,745,363; 5,745,735; 5,777,360; 5,781,439; 5,781,446; 5,784,287; 5,789,770; 5,793,644; 5,796,625; 5,798,936; 5,801,422; 5,801,958; 5,805,861; 5,808,330; 5,808,899; 5,811,863; 5,812,740; 5,815,403; 5,822,214; 5,828,581; 5,831,863; 5,834,821; 5,835,381; 5,838,583; 5,844,811; 5,847,965; 5,859,782; 5,864,165; 5,867,396; 5,867,398; 5,867,399; 5,870,308; 5,870,311; 5,870,312; 5,870,313; 5,872,380; 5,872,718; 5,875,117; 5,880,971; 5,883,814; 5,889,329; 5,892,688; 5,898,597; 5,903,461; 5,903,886; 5,909,376; 5,910,897; 5,912,820; 5,914,887; 5,914,888; 5,930,499; 5,933,356; 5,963,455; 5,963,730; 5,963,975; 5,971,588; 5,973,376; 5,987,086; 6,002,857; 6,009,251; 6,026,223; 6,030,110; 6,035,106; 6,045,252; 6,067,409; 6,080,204; 6,085,032; 6,086,621; 6,086,631; 6,097,073; 6,099,578; 6,099,583; 6,134,702; 6,145,117; 6,154,874; 6,155,725; 6,170,080; 6,175,950; 6,182,272; 6,216,252; 6,230,306; 6,237,129; 6,243,849; 6,243,850; 6,243,851; 6,247,167; 6,253,363; 6,256,768; 6,260,183; 6,269,469; 6,279,045; 6,282,693; 6,289,495; 6,292,929; 6,298,468; 6,301,693; 6,312,980; 6,317,865; 6,323,050; 6,324,674; 6,324,678; 6,327,694; 6,330,707; 6,370,673; 6,374,394; 6,405,355; 6,405,356; 6,407,434; 6,412,100; 6,415,428; 6,430,732; 6,430,734; 6,434,733; 6,434,734; 6,438,736; 6,442,743; 6,446,239; 6,446,248; 6,449,761; 6,470,482; 6,476,497; 6,477,687; 6,480,991; 6,487,697; 6,487,708; 6,493,658; 6,493,863; 6,496,967; 6,507,937; 6,507,938; 6,513,148; 6,516,454; 6,516,455; 6,516,456; 6,519,743; 6,519,745; 6,526,543; 6,526,553; 6,526,562; 6,530,063; 6,532,577; 6,532,578; 6,536,016; 6,550,042; 6,557,145; 6,560,761; 6,564,366; 6,574,779; 6,587,990; 6,588,003; 6,594,808; 6,609,238; 6,611,951; 6,618,849; 6,622,291; 6,625,780; 6,651,233; 6,651,237; 6,654,943; 6,671,864; 6,671,866; 6,678,872; 6,684,373; 6,687,892; 6,687,893; 6,693,452; 6,701,289; 6,701,474; 6,701,493; 6,701,496; 6,704,915; 6,725,389; 6,725,437; 6,728,944; 6,734,046; 6,735,744; 6,738,960; 6,745,379; 6,757,874; 6,766,500; 6,766,501; 6,792,585; 6,795,958; 6,799,309; 6,802,049; 6,807,659; 6,810,434; 6,817,016; 6,823,501; 6,823,510; 6,826,737; 6,829,754; 6,829,757; 6,836,753; 6,848,091; 6,854,093; 6,854,096; 6,857,116; 6,859,916; 6,862,731; 6,865,721; 6,865,726; 6,868,536; 6,877,146; 6,877,149; 6,882,055; 6,883,154; 6,883,156; 6,886,149; 6,889,326; 6,889,372; 6,892,371; 6,894,624; 6,895,569; 6,898,772; 6,898,773; 6,898,774; 6,901,562; 6,904,580; 6,904,584; 6,907,588; 6,907,593; 6,910,198; 6,910,199; 6,915,501; 6,915,504; 6,928,633; 6,931,616; 6,938,234; 6,944,841; 6,951,005; 6,951,006; 6,952,815; 6,952,816; 6,957,408; 6,957,409; 6,957,410; 6,957,411; 6,968,514; 6,973,634; 6,976,238; 6,981,235; 6,983,427; 6,983,439; 6,983,440; 6,988,253; 6,988,256; 7,003,754; 7,010,789; 7,013,445; 7,013,450; 7,013,451; 7,020,863; 7,024,636; 7,024,638; 7,024,650; 7,032,201; 7,036,103; 7,036,105; 7,047,163; 7,051,307; 7,055,120; 7,058,913; 7,062,743; 7,069,530; 7,073,150; 7,080,329; 7,080,336; 7,089,519; 7,089,521; 7,089,523; 7,089,524; 7,089,526; 7,093,220; 7,093,224; 7,096,445; 7,096,448; 7,096,449; 7,100,128; 7,100,129; 7,100,137; 7,100,140; 7,103,863; 7,105,385; 7,107,564; 7,107,568; 7,114,141; 7,114,142; 7,117,468; 7,117,469; 7,133,819; 7,137,097; 7,139,994; 7,143,382; 7,146,583; 7,155,693; 7,155,697; 7,178,118; 7,178,120; 7,185,305; 7,200,827; 7,216,326; 7,222,322; 7,225,116; 7,234,123; 7,237,214; 7,249,340; 7,251,800; 7,263,678; 7,266,796; 7,275,228; 7,296,251; 7,301,541; 7,305,632; 7,305,641; 7,310,793; 7,313,778; 7,337,418; 7,370,302; 7,373,473; 7,383,092; 7,398,486; 7,398,496; 7,398,498; 7,404,168; 7,437,695; 7,444,274; 7,444,499; 7,451,412; 7,451,422; 7,467,367; 7,480,879; 7,484,199; 7,490,218; 7,493,581; 7,506,295; 7,512,922; 7,516,433; 7,530,045; 7,551,985; 7,570,760; 7,574,686; 7,577,933; 7,590,960; 7,594,214; 7,596,773; 7,600,208; 7,603,640; 7,614,025; 7,617,432; 7,624,364; 7,636,876; 7,640,527; 7,653,884; 7,657,882; 7,661,078; 7,665,054; 7,669,160; 7,676,781; 7,689,940; 7,694,261; 7,698,670; 7,698,677; 7,701,255; 7,707,532; 7,711,955; 7,721,243; 7,725,848; 7,735,048; 7,739,627; 7,739,642; 7,739,644; 7,743,322; 7,743,354; 7,752,588; 7,752,590; 7,793,345; 7,805,697; 7,814,243; 7,814,451; 7,818,541; 7,823,102; 7,840,919; 7,844,437; 7,844,930; 7,856,543; 7,865,850; 7,873,927; 7,877,713; 7,890,900; 7,900,166; 7,904,840; 7,913,210; 7,917,727; 7,921,392; 7,921,393; 7,936,184; 7,937,682; 7,941,794; 7,958,480; 7,960,242; 7,964,916; 7,966,595; 7,966,597; 7,971,174; 7,986,042; 7,987,382; 8,006,212; 8,010,925; 8,015,532; 8,015,536; 8,020,124; 8,028,263; 8,032,329; 8,032,855; 8,042,087; 8,058,137; 8,065,129; 8,065,627; 8,069,429; 8,073,820; 8,108,648; 8,115,511; 8,117,569; 8,127,112; 8,136,073; 8,145,758; 8,145,848; 8,148,728; 8,151,228; 8,153,499; 8,166,214; 8,176,452; 8,185,862; 8,190,804; 8,195,883; 8,198,914; 8,201,128; 8,229,723; 8,237,228; 8,239,797; 8,239,805; 8,266,557; 8,273,610; 8,276,107; 8,281,297; 8,286,111; 8,294,159; 8,296,702; 8,296,708; 8,307,315; 8,307,316; 8,332,793; 8,347,257; 8,356,266; 8,359,553; 8,362,482; 8,365,113; 8,365,131; 8,370,783; 8,378,494; 8,392,862; 8,395,191; 8,397,197; 8,405,420; 8,407,433; 8,407,645; 8,434,044; 8,434,052; 8,438,306; 8,438,320; 8,443,326; 8,443,422; 8,445,918; 8,458,639; 8,473,891; 8,484,397; 8,495,534; 8,504,978; 8,504,992; 8,510,702; 8,514,889; 8,516,196; 8,516,412; 8,516,416; 8,526,227; 8,527,928; 8,539,402; 8,539,419; 8,549,457; 8,559,209; 8,561,005; 8,566,765; 8,572,532; 8,572,539; 8,572,541; 8,572,544; 8,584,070; 8,584,099; 8,589,845; 8,589,855; 8,595,674; 8,601,288; 8,601,423; 8,612,955; 8,635,571; 8,639,885; 8,640,066; 8,656,338; 8,661,388; 8,661,391; 8,664,042; 8,671,376; 8,683,407; 8,707,228; 8,709,880; 8,711,867; 8,745,560; 8,745,567; 8,751,983; 8,754,533; 8,789,001; 8,789,060; 8,793,633; 8,798,038; 8,806,404; 8,813,013; 8,819,608; 8,819,611; 8,819,616; 8,826,215; 8,839,171; 8,843,866; 8,863,062; 8,863,067; 8,868,941; 8,879,311; 8,898,608; 8,907,442; 8,912,052; 8,918,751; 8,929,126; 8,930,253; 8,935,642; 8,935,647; 8,966,415; 8,972,912; 8,972,995; 8,977,995; 8,984,464; 8,984,465; 8,984,467; 8,987,079; 8,990,743; 9,003,346; 9,003,349; 9,009,711; 9,020,276; 9,021,414; 9,024,657; 9,032,343; 9,038,013; 9,043,742; 9,053,285; 9,098,667; 9,104,830; 9,111,060; 9,117,052; 9,135,375; 9,136,153; 9,141,740; 9,141,743; 9,143,128; 9,152,427; 9,152,742; 9,154,137; 9,165,098; 9,165,103; 9,177,090; 9,201,999; 9,208,273; 9,213,793; 9,235,680; 9,245,082; 9,250,899; 9,251,299; 9,262,359; 9,275,002; 9,280,632; 9,292,436; 9,292,651; 9,298,868; 9,310,867; 9,317,641; 9,323,870; 9,342,652; 9,361,416; 9,361,417; 9,390,211; 9,401,202; 9,405,690; 9,405,700; 9,406,670; 9,430,601; 9,436,565; 9,436,794; 9,436,796; 9,436,848; 9,449,135; 9,454,632; 9,477,568; 9,495,290; 9,501,606; 9,515,961; 9,529,967; 9,536,036; 9,547,733; 9,558,090; 9,564,432; 9,575,891; 9,576,102; 9,576,104; 9,582,634; 9,582,635; 9,600,614; 9,600,620; 9,602,106; 9,652,576; 9,672,308; 9,679,104; 9,684,756; 9,703,923; 9,703,924; 9,711,407; 9,720,611; 9,760,667; 9,792,396; 9,792,397; 9,792,400; 9,817,929; 9,838,013; 9,846,623; 9,870,440; 9,892,223; 9,898,297; 9,910,454; 9,940,421; 9,953,132; 9,953,134; 9,953,135; 9,977,852; 10,031,686; 10,031,994; 10,055,528; 10,055,529; 10,055,531; 10,062,422; 10,068,054; 10,073,802; 10,073,942; 10,083,269; 10,083,276; 10,084,771; 10,116,557; 10,127,344; 10,140,407; 10,141,297; 10,152,112; 10,169,523; 10,181,003; 10,210,299; 10,210,308; 10,216,890; 10,235,488; 10,242,145; 10,255,396; 10,262,105; 10,268,795; 10,268,797; 10,282,505; 10,289,792; 10,289,796; 10,303,628; 10,303,828; 10,331,841; 10,339,022; 10,346,569; 10,346,577; 10,354,037; 10,354,039; 10,354,040; 10,372,859; 10,380,286; 10,380,289; 10,386,395; 10,402,530; 10,402,533; 10,409,608; 10,417,375; 10,419,338; 10,423,749; 10,423,754; 10,452,807; 10,460,062; 10,460,063; 10,460,064; 10,460,065; 10,460,066; 10,467,365; 10,474,533; 10,482,210; 10,489,549; 10,503,858; 10,515,041; 10,515,168; 10,515,177; 10,515,180; 10,528,868; 10,534,887; 10,534,891; 10,540,470; 10,552,740; 10,572,621; 10,585,603; 10,587,534; 10,614,191; 10,622,097; 10,642,951; 10,643,014; 10,657,691; 10,664,421; 10,666,641; 10,706,199; 10,713,406; 10,726,184; 10,755,020; 10,755,024; 10,766,765; 10,769,330; 10,769,341; 10,769,343; 10,771,448; 10,783,292; 10,783,312; 10,788,993; 10,796,042; 10,796,058; 10,817,641; 10,830,800; 10,831,953; 10,831,954; 10,831,965; 10,831,966; 10,831,979; 10,847,251; 10,860,229; 10,860,764; 10,867,937; 10,878,152; 10,878,166; 10,885,243; 10,885,249; 10,885,250; 10,885,256; 10,885,257; 10,885,260; 10,901,490; 10,902,174; 10,902,178; 10,908,914; 10,909,284; 10,910,364; 10,911,352; 10,921,874; 10,936,777; 10,943,040; 10,955,470; 10,963,613; 10,963,620; 10,970,245; 10,970,441; 10,977,408; 10,977,419; 10,990,739; 10,990,745; 10,997,333; 10,997,347; 10,997,350; 11,003,827; 11,018,133; 11,023,377; 11,030,371; 11,030,378; 11,030,380; 11,055,461; 11,080,456; 11,080,457; 11,087,057; 11,101,266; 11,106,853; 11,120,192; 11,126,779; 11,132,489; 11,144,218; 11,171,089; 11,182,530; 11,200,363; 11,205,032; 11,205,034; 11,216,609; 11,222,159; 11,223,573; 11,227,087; 11,231,769; 11,250,197; 11,256,837; 11,270,055; 11,275,886; 11,281,828; 11,288,425; 11,295,053; 11,301,614; 11,301,757; 11,314,920; 11,321,514; 11,333,707; 11,341,309; 11,347,923; 11,374,118; 11,379,643; 11,403,014; 11,403,448; 11,416,660; 11,429,774; 11,436,186; 11,436,402; 11,449,657; 11,449,660; 11,455,455; 11,469,131; 11,475,198; 11,481,536; 11,487,928; 11,494,542; 11,494,545; 11,501,478; 11,514,221; 11,514,222; 11,520,959; 11,520,967; 11,526,642; 11,526,650; 11,526,651; 11,533,224; 11,550,982; 11,556,690; 11,568,125; 11,568,126; 11,568,633; 11,574,107; 11,574,109; 11,586,798; 11,605,630; 11,615,228; 11,620,417; 11,625,522; 11,625,525; 20010003843; 20010010090; 20010018759; 20010034873; 20020026539; 20020066066; 20020069397; 20020073380; 20020073390; 20020083405; 20020087939; 20020087940; 20020091979; 20020100007; 20020112212; 20020116687; 20020124231; 20020133792; 20020133798; 20020147958; 20020157075; 20020166104; 20020166105; 20020170027; 20020174412; 20020178430; 20020184600; 20020184607; 20020188919; 20020194575; 20020199165; 20030006901; 20030018947; 20030023943; 20030041163; 20030043827; 20030056187; 20030063568; 20030063614; 20030064559; 20030066042; 20030066043; 20030066044; 20030066045; 20030074645; 20030079193; 20030088841; 20030088844; 20030088845; 20030101427; 20030101428; 20030115566; 20030121015; 20030126571; 20030177461; 20030188274; 20030188286; 20030192021; 20030212974; 20030217338; 20030217346; 20030221177; 20030229874; 20040010759; 20040044979; 20040068331; 20040068711; 20040073881; 20040078767; 20040078770; 20040088670; 20040098676; 20040098689; 20040103377; 20040111687; 20040117753; 20040123260; 20040123261; 20040123262; 20040128639; 20040133860; 20040133868; 20040139413; 20040168143; 20040230931; 20040230933; 20040243953; 20040243964; 20040257207; 20040267511; 20050022146; 20050028128; 20050060679; 20050076319; 20050091621; 20050108669; 20050125756; 20050138587; 20050166169; 20050166205; 20050172252; 20050183054; 20050183055; 20050204316; 20050210422; 20050251775; 20050268258; 20050268267; 20050278676; 20050289496; 20060010412; 20060010413; 20060017135; 20060026545; 20060064654; 20060064662; 20060075368; 20060075369; 20060101365; 20060112362; 20060117240; 20060129747; 20060129963; 20060136848; 20060143581; 20060156265; 20060179429; 20060190114; 20060190889; 20060190895; 20060200266; 20060206848; 20060218515; 20060230375; 20060236273; 20060236291; 20060265681; 20060271894; 20060288322; 20060288323; 20070011639; 20070033561; 20070035428; 20070044056; 20070044059; 20070061769; 20070067747; 20070089074; 20070106971; 20070108961; 20070136709; 20070143724; 20070150846; 20070157146; 20070186199; 20070198971; 20070200596; 20070204252; 20070217453; 20070220232; 20070220470; 20070220522; 20070234016; 20070234257; 20070234260; 20070245280; 20070245281; 20070266359; 20070271543; 20070271556; 20070300192; 20080005711; 20080005712; 20080005713; 20080013376; 20080022235; 20080022250; 20080022253; 20080046854; 20080066038; 20080074142; 20080098340; 20080111158; 20080127018; 20080133882; 20080134118; 20080134120; 20080155485; 20080216024; 20080216025; 20080216038; 20080216039; 20080216040; 20080222588; 20080229273; 20080235642; 20080237644; 20080244497; 20080263486; 20080276208; 20080276209; 20080276210; 20080276212; 20080301612; 20080301618; 20080301708; 20080309374; 20080313424; 20080320254; 20080320255; 20080320268; 20080320430; 20080320476; 20090013299; 20090019411; 20090019413; 20090024347; 20090024970; 20090031269; 20090031277; 20090031278; 20090045841; 20090064079; 20090064080; 20090083690; 20090089722; 20090100397; 20090111255; 20090115469; 20090115488; 20090115503; 20090116597; 20090119621; 20090119622; 20090119631; 20090125859; 20090132981; 20090150857; 20090187870; 20090193381; 20090199142; 20090210832; 20090235020; 20090254525; 20090254874; 20090271752; 20090288053; 20090313592; 20090322411; 20100001403; 20100011324; 20100031214; 20100031215; 20100031218; 20100042759; 20100050135; 20100057400; 20100115196; 20100115477; 20100131913; 20100199234; 20100199248; 20100211935; 20100218155; 20100235797; 20100259296; 20100269082; 20100289064; 20100291749; 20100295136; 20100318655; 20110016445; 20110022998; 20110023000; 20110024869; 20110035711; 20110035712; 20110049577; 20110055791; 20110055792; 20110067114; 20110083000; 20110084314; 20110092030; 20110108888; 20110121366; 20110126166; 20110131379; 20110153942; 20110154279; 20110173579; 20110173581; 20110185125; 20110191738; 20110199116; 20110202897; 20110204919; 20110213949; 20110233617; 20110233676; 20110239179; 20110252389; 20110260318; 20110289468; 20110296366; 20110317482; 20120005643; 20120012895; 20120017189; 20120028436; 20120032294; 20120036296; 20120036488; 20120036491; 20120036509; 20120038057; 20120054511; 20120054707; 20120057412; 20120060138; 20120066654; 20120096417; 20120107967; 20120110106; 20120110533; 20120117301; 20120124541; 20120129301; 20120136633; 20120151193; 20120151429; 20120174048; 20120174051; 20120180017; 20120180068; 20120185811; 20120200347; 20120216012; 20120223738; 20120233577; 20120239883; 20120240091; 20120242149; 20120248595; 20120254818; 20120266124; 20120272199; 20120273955; 20120284676; 20120290995; 20120297354; 20120303933; 20120306535; 20120314477; 20130021058; 20130021060; 20130026571; 20130026572; 20130036396; 20130047127; 20130051385; 20130051391; 20130051397; 20130055176; 20130061195; 20130073878; 20130086540; 20130086545; 20130097573; 20130097574; 20130104097; 20130111426; 20130119557; 20130125078; 20130145335; 20130154128; 20130193488; 20130212547; 20130248957; 20130263073; 20130268905; 20130290914; 20130298101; 20130311796; 20130318308; 20130329842; 20130334613; 20130334711; 20130336055; 20130339912; 20130339917; 20140044265; 20140047402; 20140053120; 20140059505; 20140075404; 20140082579; 20140082580; 20140103959; 20140103985; 20140105246; 20140115218; 20140115298; 20140115546; 20140140122; 20140149958; 20140157219; 20140165019; 20140173544; 20140181773; 20140189617; 20140189622; 20140189630; 20140195996; 20140215419; 20140215426; 20140245248; 20140282344; 20140289691; 20140298281; 20140314076; 20140325462; 20140331027; 20140346662; 20140359546; 20140359755; 20140371109; 20140371110; 20140375353; 20140380256; 20140380257; 20150007120; 20150020041; 20150026494; 20150046651; 20150049543; 20150061036; 20150091633; 20150093910; 20150113496; 20150135147; 20150137252; 20150138874; 20150179535; 20150186561; 20150186583; 20150186589; 20150199464; 20150205903; 20150212152; 20150213179; 20150220674; 20150227646; 20150234971; 20150245362; 20150248519; 20150278424; 20150286766; 20150286772; 20150302135; 20150324512; 20150324513; 20150324514; 20150331983; 20150363517; 20150364168; 20150370947; 20150370948; 20150370949; 20150370950; 20150370951; 20160028722; 20160034625; 20160034628; 20160042110; 20160048394; 20160063163; 20160063165; 20160078165; 20160078170; 20160085886; 20160085897; 20160085898; 20160091405; 20160098508; 20160103941; 20160117436; 20160125116; 20160140290; 20160147928; 20160154056; 20160154924; 20160162622; 20160163385; 20160180002; 20160180019; 20160188501; 20160188774; 20160188779; 20160192205; 20160203254; 20160210396; 20160217243; 20160224709; 20160232271; 20160232272; 20160232274; 20160232275; 20160232276; 20160239599; 20160246923; 20160246924; 20160267204; 20160267215; 20160275230; 20160283632; 20160292329; 20160300005; 20160321081; 20160323143; 20160335386; 20160342722; 20160344629; 20160363985; 20170004240; 20170010831; 20170011139; 20170011163; 20170017746; 20170052857; 20170061060; 20170061063; 20170061065; 20170068765; 20170068769; 20170083469; 20170083660; 20170083662; 20170083812; 20170091365; 20170091374; 20170103156; 20170124254; 20170126425; 20170132341; 20170132349; 20170140800; 20170169155; 20170169165; 20170212739; 20170212970; 20170212975; 20170212977; 20170220499; 20170228486; 20170236814; 20170249099; 20170255744; 20170277830; 20170286585; 20170293706; 20170302277; 20170337321; 20170344686; 20170351798; 20170364296; 20170364625; 20180012795; 20180060475; 20180089505; 20180096981; 20180107537; 20180121291; 20180122793; 20180144079; 20180144086; 20180150583; 20180150584; 20180150586; 20180150592; 20180157782; 20180165400; 20180181403; 20180189440; 20180196906; 20180196917; 20180210994; 20180218108; 20180231604; 20180232481; 20180239858; 20180239859; 20180239860; 20180239865; 20180246834; 20180246996; 20180260017; 20180260018; 20180260498; 20180268015; 20180287964; 20180293344; 20180301185; 20180302281; 20180307790; 20180341736; 20180341738; 20180342468; 20180364931; 20190012420; 20190028387; 20190034572; 20190034575; 20190049912; 20190065655; 20190065656; 20190065657; 20190079578; 20190097999; 20190102489; 20190147981; 20190163862; 20190163863; 20190164619; 20190171783; 20190172552; 20190172558; 20190179974; 20190179992; 20190188351; 20190188353; 20190211475; 20190214377; 20190236234; 20190237461; 20190258921; 20190266089; 20190272868; 20190286783; 20190286784; 20190303527; 20190332740; 20190340324; 20190347380; 20190354653; 20190362043; 20190377580; 20190384884; 20190392089; 20200004910; 20200004912; 20200006481; 20200019667; 20200019670; 20200019672; 20200020699; 20200034506; 20200057836; 20200058586; 20200074042; 20200074045; 20200082032; 20200097634; 20200104447; 20200104451; 20200104453; 20200104462; 20200117768; 20200125690; 20200132763; 20200134120; 20200134121; 20200134124; 20200134125; 20200134133; 20200135637; 20200142851; 20200142857; 20200151297; 20200152567; 20200159882; 20200175216; 20200201949; 20200213245; 20200241879; 20200242294; 20200259743; 20200272343; 20200272781; 20200350310; 20200365583; 20200372124; 20200401179; 20200401753; 20210012052; 20210019465; 20210034805; 20210042461; 20210056175; 20210058387; 20210064716; 20210064719; 20210064806; 20210073343; 20210073347; 20210089221; 20210089630; 20210104517; 20210110095; 20210117608; 20210125981; 20210134640; 20210160177; 20210165856; 20210173576; 20210192112; 20210193261; 20210203557; 20210210430; 20210240900; 20210242205; 20210248297; 20210256188; 20210256192; 20210256193; 20210264089; 20210272963; 20210287036; 20210294958; 20210313319; 20210334445; 20210349845; 20210357567; 20210357568; 20210358847; 20220012177; 20220035983; 20220037307; 20220050952; 20220065926; 20220067262; 20220075922; 20220092248; 20220108058; 20220108059; 20220129613; 20220138385; 20220147689; 20220147691; 20220164513; 20220180037; 20220187785; 20220188499; 20220197729; 20220198122; 20220222411; 20220222414; 20220254712; 20220269847; 20220300687; 20220300688; 20220300689; 20220300692; 20220310598; 20220318477; 20220318480; 20220327272; 20220328409; 20220328474; 20220335191; 20220335193; 20220344255; 20220344258; 20220358276; 20220366116; 20220374578; 20220375898; 20220375920; 20220382946; 20220391566; 20220405455; 20220415377; 20220415378; 20220417177; 20230004698; 20230008569; 20230012640; 20230024684; 20230027655; 20230032510; 20230034219; 20230034736; 20230036710; 20230046865; 20230047575; 20230047911; 20230048541; 20230050432; 20230052310; 20230057293; 20230062400; 20230064525; 20230067734; 20230072923; 20230085561; 20230095204; 20230101438; and 20230101678.
Foreign Patent Nos. EP1543449B1, EP3425541A1, JP2009545829A, JP2886481B2, JP4679029B2, JPH0658935B2.

TABLE 1

| | | | FM | FM | | Clip | hMetis | hMetis | | | CLIP/H | CLIP/H |
|---|---|---|---|---|---|---|---|---|---|---|---|---|
| BM | Module | Nets | Min | Avg | CLIPMin | Avg | Min | Avg | FM/hMetis | FM/hMetis | min | avg |
| ibm01 | 12752 | 14111 | 191 | 466 | 181 | 390 | 181 | 236 | 1.06 | 1.97 | 1.00 | 1.65 |
| ibm02 | 19501 | 19584 | 266 | 506 | 265 | 545 | 262 | 312 | 1.02 | 1.62 | 1.01 | 1.75 |
| ibm03 | 23136 | 27401 | 1150 | 2131 | 1068 | 1593 | 959 | 1068 | 1.20 | 2.00 | 1.11 | 1.49 |
| ibm04 | 27507 | 31970 | 603 | 1105 | 563 | 1030 | 542 | 588 | 1.11 | 1.88 | 1.04 | 1.75 |
| ibm05 | 29374 | 28446 | 1874 | 3063 | 2146 | 3016 | 1740 | 1838 | 1.08 | 1.67 | 1.23 | 1.64 |
| ibm06 | 32498 | 34826 | 973 | 1384 | 977 | 1520 | 885 | 1023 | 1.10 | 1.35 | 1.10 | 1.49 |
| ibm07 | 45926 | 48117 | 1037 | 2036 | 929 | 1987 | 848 | 930 | 1.22 | 2.19 | 1.10 | 2.14 |
| ibm08 | 51309 | 50513 | 1285 | 2757 | 1261 | 2137 | 1159 | 1194 | 1.11 | 2.31 | 1.09 | 1.79 |
| ibm09 | 53395 | 60902 | 912 | 2547 | 674 | 1770 | 624 | 685 | 1.46 | 3.72 | 1.08 | 2.58 |
| ibm10 | 69429 | 75196 | 1490 | 2260 | 1420 | 2745 | 1265 | 1573 | 1.18 | 1.44 | 1.12 | 1.75 |
| ibm11 | 70558 | 81454 | 1459 | 4173 | 1063 | 2657 | 963 | 1146 | 1.52 | 3.64 | 1.10 | 2.32 |
| ibm12 | 71706 | 77240 | 2256 | 3791 | 2387 | 3770 | 1899 | 2133 | 1.19 | 1.78 | 1.26 | 1.77 |
| ibm13 | 84199 | 99666 | 1181 | 2249 | 913 | 1955 | 841 | 979 | 1.40 | 2.30 | 1.09 | 2.00 |
| ibm14 | 147605 | 152772 | 2963 | 6824 | 2356 | 4176 | 1928 | 2126 | 1.54 | 3.21 | 1.22 | 1.96 |
| ibm15 | 161570 | 186608 | 5106 | 7770 | 3571 | 5689 | 2750 | 3218 | 1.86 | 2.41 | 1.30 | 1.77 |
| ibm16 | 183484 | 190048 | 2363 | 5668 | 2638 | 5974 | 1758 | 2339 | 1.34 | 2.42 | 1.50 | 2.55 |
| ibm17 | 185495 | 189581 | 3052 | 7212 | 2803 | 6998 | 2341 | 2430 | 1.30 | 2.97 | 1.20 | 2.88 |
| ibm18 | 210613 | 201920 | 1706 | 3686 | 2268 | 5227 | 1528 | 1669 | 1.12 | 2.21 | 1.48 | 3.13 |

| | | | | |
|---|---|---|---|---|
| Ratio: | 1.27 | 2.28 | 1.17 | 2.02 |

Partitioning results from the ISPD98 benchmark set, taken from {13}. Each heuristic was run multiple times, with the minimum, maximum, and average cuts shown. Note that hMetis beats the other methods by a wide margin, while also having consistent results.

TABLE 2

| | Nodes | Edges | Min | Max | Average |
|---|---|---|---|---|---|
| Flat | 12752 | 14111 | 9034 | 9438 | 9225.5 |
| 1st | 8118 | 10093 | 6859 | 7168 | 7025.4 |
| 2nd | 5380 | 7772 | 5516 | 5812 | 5657.1 |
| 3rd | 3675 | 6434 | 4642 | 4948 | 4797.6 |
| 4th | 2614 | 5571 | 4042 | 4329 | 4191.1 |
| 5th | 1977 | 4998 | 3606 | 3922 | 3762.5 |
| 6th | 1592 | 4562 | 3281 | 3613 | 3444.3 |
| 7th | 1347 | 4281 | 3016 | 3445 | 3222.0 |
| 8th | 1193 | 4077 | 2829 | 3247 | 3049.0 |
| 9th | 1084 | 3930 | 2666 | 3135 | 2923.8 |
| 10th | 1019 | 3825 | 2597 | 3046 | 2849.6 |

Clustering of a graph improves the average cut of a random partition. The solution space for the clustered graph is a subset of the solution space for the “parent” graph, and in particular, a subset consisting mostly of “better” configurations.

TABLE 3

| | | | | | % Cell | % Macro |
|---|---|---|---|---|---|---|
| Benchmark | #Nets | #Cells | #Macro | #Pads | Area | Area |
| ibm01 | 14111 | 12260 | 246 | 246 | 37.23 | 42.76 |
| ibm02 | 19584 | 19071 | 271 | 259 | 24.69 | 55.31 |
| ibm03 | 27401 | 22563 | 290 | 283 | 30.04 | 49.96 |
| ibm04 | 31970 | 26925 | 295 | 287 | 38.03 | 41.98 |
| ibm05 | 28446 | 28146 | 0 | 1201 | 80.01 | 0.00 |
| ibm06 | 34826 | 32154 | 178 | 166 | 34.60 | 45.41 |
| ibm07 | 48117 | 45348 | 291 | 287 | 44.07 | 35.93 |
| ibm08 | 50513 | 50722 | 301 | 286 | 38.79 | 41.20 |
| ibm09 | 60902 | 52857 | 253 | 285 | 40.18 | 39.82 |
| ibm10 | 75196 | 67899 | 786 | 744 | 20.34 | 59.66 |
| ibm11 | 81454 | 69779 | 373 | 406 | 42.36 | 37.63 |
| ibm12 | 77240 | 69788 | 651 | 637 | 28.35 | 51.65 |
| ibm13 | 99666 | 83285 | 424 | 490 | 43.82 | 36.18 |
| ibm14 | 152772 | 146474 | 614 | 517 | 60.36 | 19.64 |
| ibm15 | 186608 | 160794 | 393 | 383 | 53.26 | 26.74 |
| ibm16 | 190048 | 182522 | 458 | 504 | 42.11 | 37.89 |
| ibm17 | 189581 | 183992 | 760 | 743 | 62.80 | 17.20 |
| ibm18 | 201920 | 210056 | 285 | 272 | 71.31 | 8.69 |

Statistics for the 18 IBM mixed size Benchmarks {14}. In each design, there is roughly 20% white space available.

TABLE 4

| | Capo I {14} | | Capo II {17} | | Capo III {17} | | mPG {18} | | Feng Shui 2.4 | | | | |
|---|---|---|---|---|---|---|---|---|---|---|---|---|---|
| Bench | | CPU | | CPU | | CPU | | CPU | | % Better | % Better | CPU | Legal. |
| mark | HPWL | (min) | HPWL | (min) | HPWL | (min) | HPWL | (min) | HPWL | (Capo) | (MPG) | (min) | (sec) |
| ibm01 | 3.96 | 18 | 3.36 | 13 | 3.05 | 20 | 3.01 | 18 | 2.41 | 26.56 | 24.90 | 3 | 1 |
| ibm02 | 8.37 | 31 | 8.23 | 240 | 6.83 | 11 | 7.42 | 32 | 5.34 | 27.90 | 38.95 | 5 | <1 |
| ibm03 | 12.16 | 42 | 11.53 | 22 | 10.38 | 59 | 11.20 | 32 | 7.51 | 38.22 | 49.13 | 6 | 2 |
| ibm04 | 13.48 | 47 | 11.93 | 25 | 10.11 | 15 | 10.50 | 42 | 7.96 | 27.01 | 31.91 | 7 | <1 |
| ibm05 | 11.51 | 8 | 11.20 | 5 | 11.10 | 5 | 10.90 | 36 | 10.10 | 9.90 | 7.92 | 8 | 1 |
| ibm06 | 10.25 | 56 | 9.63 | 19 | 9.94 | 18 | 9.21 | 45 | 6.82 | 41.20 | 35.04 | 10 | 2 |
| ibm07 | 15.75 | 58 | 15.80 | 39 | 15.25 | 25 | 13.70 | 68 | 11.71 | 30.23 | 16.99 | 13 | 1 |
| ibm08 | 21.18 | 94 | 18.85 | 111 | 17.91 | 29 | 16.40 | 82 | 13.60 | 31.69 | 20.59 | 16 | 1 |
| ibm09 | 19.59 | 66 | 17.52 | 178 | 19.88 | 29 | 18.60 | 84 | 13.83 | 26.68 | 34.49 | 15 | 1 |
| ibm10 | 60.72 | 229 | 53.58 | 490 | 45.46 | 116 | 43.60 | 172 | 37.48 | 21.29 | 16.33 | 22 | 17 |
| ibm11 | 28.49 | 106 | 26.47 | 69 | 29.40 | 45 | 26.50 | 112 | 19.96 | 32.62 | 32.77 | 21 | 2 |
| ibm12 | 51.74 | 675 | 55.12 | 119 | 55.79 | 25 | 44.30 | 153 | 35.57 | 45.46 | 24.54 | 23 | 3 |
| ibm13 | 39.39 | 151 | 33.56 | 88 | 37.73 | 53 | 37.70 | 151 | 24.95 | 34.51 | 51.10 | 26 | 2 |
| ibm14 | 56.19 | 286 | 52.67 | 333 | 50.26 | 155 | 43.50 | 276 | 38.48 | 30.61 | 13.05 | 52 | 5 |
| ibm15 | 70.48 | 237 | 64.69 | 264 | 65.00 | 195 | 65.50 | 385 | 52.14 | 24.07 | 25.62 | 87 | 10 |
| ibm16 | N/A | N/A | 183.14 | 580 | 90.01 | 162 | 72.40 | 436 | 61.33 | 35.56 | 18.05 | 93 | 15 |
| ibm17 | 92.38 | 443 | 91.50 | 249 | 89.17 | 188 | 78.50 | 606 | 70.60 | 26.30 | 11.19 | 104 | 16 |
| ibm18 | 54.90 | 378 | 54.11 | 397 | 51.84 | 127 | 50.70 | 437 | 45.05 | 15.07 | 12.54 | 114 | 18 |
| Avg | | | | | | | | | | 29.16 | 25.84 | | |

Half perimeter wire length (HPWL) and runtime comparisons for the IBM benchmarks between Capo, mPG, and the present tool. For ratio comparisons with Capo, their best result is used. Run times cannot be directly compared: The present experiments use 2.5 GHz Linux/Pentium 4 workstations, Capo I used 1 GHz Linux/Pentium 3 workstations, Capo II and III used 2 GHz Linux/Pentium 4 workstations, and mPG used 750 MHz Sun Blade 1000 workstations. All run times are in minutes, with the exception of the legalization step of the present tool, which is in seconds.

TABLE 5

| Benchmark | Capo | mPG-MS | feng shui | Aplace | Uplace |
|---|---|---|---|---|---|
| ibm01 | 0.31 | 0.30 | 0.24 | 0.23 | 0.25 |
| ibm02 | 0.68 | 0.74 | 0.53 | 0.50 | 0.54 |
| ibm03 | 1.04 | 1.20 | 0.75 | 0.72 | 0.73 |
| ibm04 | 1.01 | 1.05 | 0.80 | 0.83 | 0.82 |
| ibm05 | 1.11 | 1.09 | 1.01 | 0.98 | 1.09 |
| ibm06 | 0.99 | 0.92 | 0.68 | 0.68 | 0.67 |
| ibm07 | 1.53 | 1.37 | 1.17 | 1.05 | 1.18 |
| ibm08 | 1.79 | 1.64 | 1.36 | 1.46 | 1.34 |
| ibm09 | 1.99 | 1.86 | 1.38 | 1.38 | 1.48 |
| ibm10 | 4.55 | 4.36 | 3.75 | 3.00 | 3.52 |

In 2004/2005, analytic placement tools closed the gap with recursive bisection, obtaining results within a few percentage points for the ten smallest examples in the IBM mixed size suite.

TABLE 6

| Benchmark | APlace2 | feng shui | SCAMPI |
|---|---|---|---|
| 040 | 20.70 | 20.60 | 18.80 |
| 098 | 22.60 | 24.00 | 30.70 |
| 336 | 2.20 | 7.60 | 3.30 |
| 353 | 4.60 | 31.50 | 6.30 |
| 523 | 27.50 | 348.70 | 37.10 |
| 542 | 0.70 | x | 0.80 |
| 566 | 46.90 | 493.60 | 69.30 |
| 583 | 20.60 | x | 25.10 |
| 588 | 4.80 | x | 6.90 |
| 643 | 3.00 | 15.30 | 3.70 |
| DCT | 33.10 | 184.70 | 37.20 |

When placing large numbers of macros, the puzzle fitting element can be difficult to handle effectively. For the cal benchmark set, feng shui exhibited worst case behavior for most designs, with dramatic increases in interconnect length, and frequent overlap violations. The fixed-outline floor plan centric approach of scampi performed much better.

TABLE 7

| Placer | Adaptec2 | Adaptec4 | BigBlue1 | BigBlue2 | BigBlue3 | BigBlue4 | Ratio |
|---|---|---|---|---|---|---|---|
| Aplace | 87.31 | 187.65 | 94.64 | 143.00 | 357.89 | 833.21 | 1.00 |
| mFAR | 91.53 | 190.84 | 97.70 | 168.70 | 379.95 | 875.28 | 1.06 |
| dragon | 94.72 | 200.88 | 102.39 | 159.71 | 380.45 | 903.96 | 1.08 |
| mPL | 97.11 | 200.94 | 98.31 | 173.22 | 369.66 | 904.19 | 1.09 |
| FastPlace | 107.86 | 204.48 | 101.56 | 169.89 | 458.49 | 889.87 | 1.16 |
| Capo | 99.71 | 211.25 | 108.21 | 172.30 | 382.63 | 1098.76 | 1.17 |
| NTUplace | 100.31 | 206.45 | 106.54 | 190.66 | 411.81 | 1154.15 | 1.21 |
| feng shui 5.0 | 122.99 | 337.22 | 114.57 | 285.43 | 471.15 | 1040.05 | 1.50 |
| Kraftwerk | 157.65 | 352.01 | 149.44 | 322.22 | 656.19 | 1403.79 | 1.84 |

Placement results for the ISPD05 contest. These designs, provided by IBM, contain a number of large fixed macro blocks. The best performing tool, Aplace, used an analytic approach, while the recursive bisection tool feng shui fared poorly, and was unable to manage the excess space and fixed macro blocks. In the 2006 iteration of the contest, the ordering of placement tools changed dramatically.

TABLE 8

| | | | | | | | | | | | | | | | | Ratio |
|---|---|---|---|---|---|---|---|---|---|---|---|---|---|---|---|---|
| | | | Weighting | | δT | CU.POKer | | | Ours | | | Ratio vs CU.POKer | | | | δt |
| BM | \|k\| | \|c\| | δT | WL | Bound | δT | WL | Score | δT | WL | Score | δT | WL | Score | Util. | bnd |
| A | 18 | 17 | 1 | 1 | 33152 | 34496 | 1314 | 35810 | 34496 | 1314 | 35810 | 1.000 | 1.000 | 1.000 | 0.972 | 1.041 |
| B | 34 | 33 | 1 | 1 | 62181 | 63504 | 2639.5 | 66143.5 | 64512 | 1913 | 66545 | 1.016 | 0.752 | 1.004 | 0.979 | 1.037 |
| C | 102 | 133 | 1 | 1 | 60270 | 64512 | 2408 | 66920 | 64512 | 4108 | 68620 | 1.000 | 1.706 | 1.025 | 0.927 | 1.070 |
| D | 54 | 69 | 1 | 1 | 32256 | 33713 | 2722 | 36435 | 33712 | 3588 | 37300 | 1.000 | 1.318 | 1.024 | 0.976 | 1.045 |
| E | 17 | 17 | 1 | 10 | 33152 | 39312 | 562 | 44932 | 34496 | 1314 | 47636 | 0.877 | 2.338 | 1.060 | 0.972 | 1.041 |
| F | 34 | 33 | 1 | 10 | 62181 | 65170 | 1489.5 | 80065 | 64512 | 1913 | 83642 | 0.990 | 1.284 | 1.045 | 1.980 | 1.037 |
| G | 102 | 133 | 1 | 10 | 60270 | 64512 | 2508.5 | 89597 | 64512 | 4108 | 105592 | 1.000 | 1.638 | 1.179 | 0.927 | 1.070 |
| H | 54 | 69 | 1 | 10 | 32256 | 39520 | 1104.5 | 50565 | 33712 | 3588 | 69592 | 0.853 | 3.249 | 1.376 | 0.976 | 1.045 |
| I | 27 | 26 | 1 | 4 | 46592 | 52136 | 617.5 | 54606 | 49280 | 1504 | 55296 | 0.945 | 2.436 | 1.013 | 0.978 | 1.058 |
| J | 81 | 105 | 1 | 4 | 45752 | 50274 | 2472.5 | 60164 | 49224 | 4631 | 66668 | 0.979 | 1.764 | 1.108 | 0.951 | 1.076 |
| K | 18 | 17 | 1 | 4 | 252 | 432 | 240 | 1392 | 252 | 423 | 1944 | 0.583 | 1.763 | 1.397 | 0.594 | 1.000 |
| L | 54 | 69 | 1 | 4 | 252 | 864 | 279 | 1980 | 252 | 867 | 3720 | 0.292 | 3.108 | 1.879 | 0.564 | 1.000 |
| M | 25 | 28 | 1 | 4 | 2156544 | 221840 | 3610.5 | 2226282 | 2322432 | 3644 | 2337008 | 1.050 | 1.009 | 1.050 | 0.956 | 1.077 |
| N | 28 | 27 | 1 | 4 | 1020 | 1482 | 480.5 | 3404 | 1035 | 1490 | 6995 | 0.698 | 3.101 | 2.055 | 0.985 | 1.015 |
| O | 27 | 26 | 1 | 40 | 46592 | 52136 | 617.5 | 76836 | 49280 | 1504 | 109440 | 0.945 | 2.736 | 1.424 | 0.978 | 1.058 |
| P | 81 | 105 | 1 | 40 | 45752 | 57792 | 1101 | 101832 | 49224 | 4361 | 223664 | 0.852 | 3.961 | 2.196 | 0.951 | 1.076 |
| Q | 18 | 17 | 1 | 40 | 252 | 882 | 166 | 7522 | 252 | 423 | 17172 | 0.286 | 2.548 | 2.283 | 0.594 | 1.000 |
| R | 54 | 69 | 1 | 40 | 252 | 8064 | 259 | 18424 | 252 | 867 | 34932 | 0.031 | 3.347 | 1.896 | 0.564 | 1.000 |
| S | 25 | 28 | 1 | 400 | 2156544 | 2396300 | 1879.5 | 3155300 | 2322432 | 3644 | 3780032 | 0.969 | 1.920 | 1.198 | 0.956 | 1.077 |
| T | 28 | 27 | 1 | 40 | 1020 | 4102 | 208.5 | 12442 | 1035 | 1490 | 60635 | 0.252 | 7.146 | 4.873 | 0.985 | 1.015 |
| | | | | | | | | | | | Avg: | 0.781 | 2.390 | 1.554 | 0.888 | 1.042 |

Experimental results for the ISPD benchmarks; k and c denote the number of compute kernels and inter-kernel connections. By considering all non-dominated kernel configurations, we can identify bounds for δt. Our approach produces low delay solutions, but significantly higher interconnect costs compared to CU.POKer. Restricting the placement to horizontal rows still enables excellent wire lengths, only slightly higher delay than the theoretical bounds, and almost complete utilization of all available processor cores.

TABLE 9

| | | Multiple CS-1 δT | | | | | |
|---|---|---|---|---|---|---|---|
| BM | Single CS-1 δT | 1 | 2 | 3 | 4 | Max δT | Speedup |
| A | 34496 | 10752 | 9072 | 8960 | 6652 | 10752 | 3.21 |
| B | 63504 | 15792 | 15876 | 16128 | 15435 | 16128 | 3.94 |
| C | 62720 | 16128 | 15680 | 15680 | 15435 | 16128 | 6.89 |
| D | 33516 | 9072 | 9702 | 9324 | 6504 | 9702 | 3.45 |
| I | 48216 | 13608 | 12096 | 12432 | 10045 | 13608 | 3.54 |
| J | 47628 | 12096 | 12096 | 12096 | 11340 | 12096 | 3.94 |
| M | 2228224 | 516096 | 681984 | 576576 | 342133 | 681984 | 3.27 |
| | | | | | | Avg: | 3.61 |

ISPD benchmark graphs, divided across multiple CS-1 wafer scale engines, using a simple greedy approach. Substantial speed-up is possible in most cases.

1. A method of laying out an integrated circuit, comprising:
defining a netlist of circuit elements comprising a plurality of macro blocks and standard cells of the integrated circuit, and associated kernel graphs, each macro block and standard cell having a respective area requirement;
obtaining a hierarchical abstract relative positioning of the circuit elements, and associated kernel graphs, within a hierarchy of regions, by at least one of repeatedly partitioning the netlist using bisection, and inducing cut lines into an abstract placement generated by an analytic placement tool;
storing the hierarchical abstract relative positioning (SHARP) of the circuit elements;
defining a plurality of arrangements of the macro blocks and standard cells within a respective region utilizing the SHARP;
iteratively legalizing the plurality of arrangements of the macro blocks and standard cells, and the associated kernel graphs, within the respective region to form legalized regions, using a plurality of legalization techniques for each respective arrangement, each legalized region meeting the area requirements of the circuit elements within each respective region, wherein in each iteration of the legalization, at least a portion of the SHARP is reused; and
merging the legalized regions to generate a set of potential placements.

2. The method according to claim 1, wherein the hierarchical abstract relative positioning of the circuit elements is obtained by repeatedly partitioning the netlist using bisection.

3. The method according to claim 1, wherein the hierarchical abstract relative positioning of the circuit elements is obtained by inducing cut lines into an abstract placement generated by an analytic placement tool.

4. The method according to claim 1, further comprising, for at least one bisected region that does not comprise exclusively macro blocks:
altering an aspect ratio of the bisected region that does not comprise exclusively macro blocks; and
altering contained macro block and standard cell positions within the bisected region that does not comprise exclusively macro blocks based on the altered aspect ratio.

5. The method according to claim 1, wherein the respective region is rectangular, further comprising altering an aspect ratio of a bisected respective region while meeting the respective area requirement of a macro block, and altering standard cell positions within the altered aspect ratio bisected respective region.

6. The method according to claim 1, wherein the hierarchical abstract relative positioning of the circuit elements comprises a tree, said obtaining the hierarchical abstract relative positioning of the circuit elements within the hierarchy of regions comprises inducing cut lines in the tree to produce a cut tree,
the method further comprising pruning the cut tree using pareto optimization.

7. The method according to claim 6, further comprising pruning the cut trees according to at least one of a feasibility criterion and a performance characteristic.

8. The method according to claim 1, further comprising:
comparing performance-related characteristics of the potential placements; and
selecting a potential placement according to the compared performance-related characteristics.

9. The method according to claim 1, further comprising annotating or altering a SHARP with netlist and circuit element changes dependent on a performance optimization of a circuit according to a respective legalized region.

10. The method according to claim 1, further comprising:
modifying a size of a respective circuit element; and
defining a second plurality of arrangements of the modified size respective circuit element within a respective region re-utilizing at least one SHARP;
said iteratively legalizing comprising legalizing the second plurality of arrangements of the macro blocks and standard cells within the respective region and associated kernel graphs to form second legalized regions, and the second legalized regions are merged to generate a second set of potential placements.

11. The method according to claim 1, further comprising annotating or altering a SHARP by replacing a macro block with a SHARP that represents an internal structure of the macro block, wherein the SHARP that represents an internal structure of the macro block relieves the respective area requirement of the macro block.

12. The method according to claim 1, wherein the plurality of arrangements of the macro blocks and standard cells within the respective region are legalized using dynamic programming.

13. The method according to claim 12, wherein the dynamic programming performs kernel selection and mapping.

14. The method according to claim 13, wherein a respective kernel graph is traversed from inputs to outputs, in breadth-first order, and the order in which kernels are encountered by traversal is selected as the order in which to place kernels across the layout.

15. The method according to claim 14, wherein a non-dominated subset of potential placements is determined using Bentley's divide and conquer algorithm.

16. The method according to claim 13,
wherein non-dominated horizontal sequential subsets of kernels are determined with the dynamic programming, and the non-dominated horizontal sequential subsets of kernels are arranged as strips,
the method further comprising stacking the strips into horizontal rows using dynamic programming.

17. The method according to claim 16, wherein alternate strips are disposed in reverse order, to create a serpentine pattern.

18. A system for laying out an integrated circuit, comprising:
an input configured to receive a netlist of circuit elements comprising a plurality of macro blocks and standard cells of the integrated circuit and associated kernel graphs, each macro block and standard cell having a respective area requirement;
at least one automated processor, configured to:
obtain a hierarchical abstract relative positioning of the circuit elements and associated kernel graphs, within a hierarchy of regions, by at least one of repeatedly partition the netlist using bisection, and induction of cut lines into an abstract placement generated by an analytic placement tool;
store the hierarchical abstract relative positioning (SHARP) of the circuit elements in a memory;
define a plurality of arrangements of the macro blocks and standard cells within a respective region utilizing the SHARP;
iteratively legalize the plurality of arrangements of the macro blocks and standard cells, and associated kernel graphs, within the respective region to form legalized regions, using a plurality of legalization techniques for each respective arrangement, each legalized region meeting the area requirements of the circuit elements within each respective region, wherein in each iteration of the legalization, at least a portion of the SHARP is reused; and
merge the legalized regions to generate a set of potential placements;
an output port configured to communicate the set of potential placements.

19. The system according to claim 18, wherein the at least one processor is further configured to:
annotate or alter a SHARP with netlist and circuit element changes dependent on performance optimization of a circuit; and
utilize the annotated or altered SHARP in a subsequent legalization.

20. The system according to claim 18, wherein the hierarchical abstract relative positioning of the circuit elements comprises a tree, the hierarchical abstract relative positioning of the circuit elements within the hierarchy of regions is obtained by inducing cut lines in the tree to produce a cut tree, and
the at least one processor is further configured to assess a legalized bisected region or set of potential placements dependent on the cut tree according to at least one of a feasibility criterion, a performance characteristic, and a pareto optimization, and to prune the cut tree based the on at least one of the feasibility criterion, the performance characteristic, and the pareto optimization.

21. The system according to claim 18, wherein the plurality of arrangements are legalized using dynamic programming to perform kernel selection and mapping.

22. A non-transitory medium, storing instructions for a programmable processor for laying out an integrated circuit based on a netlist of circuit elements comprising a plurality of macro blocks and standard cells of the integrated circuit, each macro block and standard cell having a respective area requirement, comprising:
instructions for obtaining a hierarchical abstract relative positioning of the circuit elements within a hierarchy of regions, by at least one of repeatedly partitioning the netlist using bisection, and inducing cut lines into an abstract placement generated by an analytic placement tool;
instructions for storing the hierarchical abstract relative positioning (SHARP) of the circuit elements;
instructions for defining a plurality of arrangements of the macro blocks and standard cells within a respective region utilizing the SHARP;
instructions for legalizing the plurality of arrangements of the macro blocks and standard cells within the respective region to form legalized regions, using a plurality of legalization techniques for each respective arrangement, each legalized region being rectangular and meeting the area requirements of the circuit elements within each respective region, wherein in each iteration of the legalization, at least a portion of the SHARP of the circuit elements is reused; and
instructions for merging the legalized regions to generate a set of potential placements.
